(19) United States
(12) Patent Application Publication
(10) Pub. No.: US 2016/0163869 A1
(43) Pub. Date: Jun. 9, 2016

(54) TRANSISTOR

(71) Applicant: SEMICONDUCTOR ENERGY LABORATORY CO., LTD., Atsugi-shi (JP)

(72) Inventors: Shunpei YAMAZAKI, Tokyo (JP); Motoki NAKASHIMA, Atsugi (JP)

(21) Appl. No.: 14/959,163

(22) Filed: Dec. 4, 2015

(30) Foreign Application Priority Data
Dec. 8, 2014 (JP) 2014-247831

(51) Int. Cl. H01L 29/786; H01L 29/423

(52) U.S. Cl. CPC H01L 29/7869; H01L 29/42384

(57) ABSTRACT

Change in electric characteristics of a semiconductor device including a transistor having a crystalline oxide semiconductor is suppressed, and reliability thereof is improved. Furthermore, a semiconductor device with low power consumption is provided. The transistor includes a gate electrode, a gate insulator, and an oxide semiconductor including a crystal. The oxide semiconductor includes hydrogen or hydroxy group. The number of released gas molecules observed as water molecules with a thermal desorption spectrometer is 1.0/nm³ or less.

### BACKGROUND OF THE INVENTION

1. Field of the Invention

The present invention relates to, for example, an oxide, a transistor, a semiconductor device, and manufacturing methods thereof. The present invention relates to, for example, an oxide, a display device, a light-emitting device, a lighting device, a power storage device, a memory device, a processor, or an electronic device. The present invention relates to a manufacturing method of an oxide, a display device, a liquid crystal display device, a light-emitting device, a memory device, or an electronic device. The present invention relates to a driving method of a semiconductor device, a display device, a liquid crystal display device, a light-emitting device, a memory device, and an electronic device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

2. Description of the Related Art

A technique for forming a transistor by using a semiconductor over a substrate having an insulating surface has attracted attention. The transistor is applied to a wide range of semiconductor devices such as an integrated circuit and a display device. Silicon is known as a semiconductor applicable to a transistor.

As silicon which is used as a semiconductor of a transistor, either amorphous silicon or polycrystalline silicon is used depending on the purpose. For example, in the case of a transistor included in a large display device, it is preferable to use amorphous silicon, which can be used to form a film on a large substrate with the established technique. On the other hand, in the case of a transistor included in a high-performance display device where driver circuits are formed over the same substrate, it is preferred to use polycrystalline silicon, which can form a transistor having high field-effect mobility. As a method for forming polycrystalline silicon, high-temperature heat treatment or laser light treatment which is performed on amorphous silicon has been known.

In recent years, transistors using oxide semiconductors (typically, In—Ga—Zn oxide) have been actively developed.

Oxide semiconductors have been researched since early times. In 1988, there was a disclosure of a crystal In—Ga—Zn oxide that can be used for a semiconductor element (see Patent Document 1). In 1995, a transistor including an oxide semiconductor was invented, and its electrical characteristics were disclosed (see Patent Document 2).

In addition, a transistor including an amorphous oxide semiconductor is disclosed (see Patent Document 3). An oxide semiconductor can be formed by a sputtering method or the like, and thus can be used for a semiconductor of a transistor in a large display device. A transistor including an oxide semiconductor has high field-effect mobility; therefore, a high-performance display device where driver circuits are formed over the same substrate can be obtained. In addition, there is an advantage that capital investment can be reduced because part of production equipment for a transistor including amorphous silicon can be retrofitted and utilized.

It is known that a transistor including an oxide semiconductor has an extremely low leakage current in an off state. For example, a low-power-consumption CPU utilizing the small leakage current characteristic of a transistor including an oxide semiconductor is disclosed (see Patent Document 4). It is also disclosed that a transistor having a high field-effect mobility can be obtained by a well potential formed using an active layer including an oxide semiconductor (see Patent Document 5).

### REFERENCE

### Patent Document

[Patent Document 1] Japanese Published Patent Application No. S63-239117
[Patent Document 2] Japanese Translation of PCT International Application No. H11-505377

### [Patent Document 3] Japanese Patent No. 5215589

### [Patent Document 4] Japanese Published Patent Application No. 2012-257187

### [Patent Document 5] Japanese Published Patent Application No. 2012-59860

### SUMMARY OF THE INVENTION

An object is to provide an element with stable electrical characteristics. An object is to provide a device including plural kinds of elements with stable electrical characteristics. Another object is to provide a transistor with stable electric characteristics. Another object is to provide a transistor having normally-off electrical characteristics. Another object is to provide a transistor having a small subthreshold swing value. Another object is to provide a transistor having a small short-channel effect. Another object is to provide a transistor having a low leakage current in an off state. Another object is to provide a transistor having excellent electrical characteristics. Another object is to provide a transistor having high reliability. Another object is to provide a transistor with high frequency characteristics.

Another object is to provide a semiconductor device including the transistor. Another object is to provide a module including any of the above semiconductor devices. Another object is to provide an electronic device including any of the above semiconductor devices or the module. Another object is to provide a novel semiconductor device. Another object is to provide a novel module. Another object is to provide a novel electronic device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a transistor including a gate electrode, a gate insulator, and a crystalline oxide semiconductor. In the transistor, the number of released gas molecules of the crystalline oxide semiconductor observed as water molecules by a thermal desorption spectrometer is 1.0/nm³ or less.

One embodiment of the present invention is a transistor including a gate electrode, a gate insulator, and a crystalline oxide semiconductor. In the transistor, the crystalline oxide semiconductor includes H or OH. The H or the OH reacts with O in the crystalline oxide semiconductor to form a water molecule when the H or the OH is released to the outside from the crystalline oxide semiconductor. The number of released gas molecules of the crystalline oxide semiconductor observed as water molecules with a thermal desorption spectrometer is 1.0/nm³ or less.

One embodiment of the present invention is a transistor including a gate electrode, a gate insulator, and a crystalline oxide semiconductor. In the transistor, the crystalline oxide semiconductor includes H or OH. The H or the OH reacts with O in the crystalline oxide semiconductor to form a water molecule when the H or the OH is released to the outside from the crystalline oxide semiconductor through a side surface of the crystalline oxide semiconductor. The number of released gas molecules observed as water molecules by a thermal desorption spectrometer is 1.0/nm³ or less.

In the above embodiments of the present invention, a water molecule does not exist in the crystalline oxide semiconductor.

In the above embodiments of the present invention, the crystalline oxide semiconductor is a CAAC-OS.

In the above embodiments of the present invention, the crystalline oxide semiconductor is a single crystal.

In the above embodiments of the present invention, the number of the released gas molecules observed is 0.1/nm³ or less.

In the above-described embodiments of the present invention, the crystalline semiconductor includes an oxide containing one or more elements selected from indium, zinc, and an element M, and the element M is aluminum, gallium, yttrium, or tin.

According to one object of one embodiment of the present invention, a change in electrical characteristics can be inhibited and reliability can be improved in a semiconductor device using a transistor including an oxide semiconductor. According to one embodiment of the present invention, a semiconductor device with low power consumption can be provided. According to one embodiment of the present invention, a novel semiconductor device can be provided.

Note that the description of these effects does not disturb the existence of other effects. One embodiment of the present invention does not necessarily achieve all of these effects. Other effects will be apparent from and can be derived from the description of the specification, the drawings, the claims, and the like.

### BRIEF DESCRIPTION OF THE DRAWINGS

FIGS. 1A and 1B are a top view and a cross-sectional view which illustrate a transistor of one embodiment of the present invention.

FIGS. 2A and 2B are a top view and a cross-sectional view which illustrate a transistor of one embodiment of the present invention.

FIGS. 3A and 3B are a top view and a cross-sectional view which illustrate the transistor of one embodiment of the present invention;

FIGS. 4A to 4D are Cs-corrected high-resolution TEM images of a cross section of a CAAC-OS and a cross-sectional schematic view of a CAAC-OS.

FIGS. 5A to 5D are Cs-corrected high-resolution TEM images of a plane of a CAAC-OS.

FIGS. 6A to 6C show structural analysis of a CAAC-OS and a single crystal oxide semiconductor by XRD.

FIGS. 7A and 7B show electron diffraction patterns of a CAAC-OS.

FIG. 8 shows a change in the crystal part of an In—Ga—Zn oxide induced by electron irradiation.

FIG. 9 shows a calculation model.

FIG. 10 shows the initial and optimized structures of the model in which H₂O is added.

FIG. 11 is a schematic view showing different areas in an InGaZnO₄ crystal.

FIGS. 12A to 12D show hydrogen transfer paths in a region between an InO₂ layer and a (Ga, Zn)O layer, and activation barriers along the paths.

FIGS. 13A and 13B show a hydrogen transfer path in the (Ga, Zn)O region and the activation barrier along the path, respectively.

FIGS. 14A and 14B show a hydrogen transfer path in the InO₂ region and the activation barrier along the path, respectively.

FIGS. 15A and 15B show a hydrogen transfer path in the c-axis direction and the activation barrier along the path, respectively.

FIG. 16 shows a calculation model.

FIG. 17 shows relative values of total energies in an oxygen vacancy model.

FIG. 18 shows a calculation model.

FIGS. 19A and 19B show models in the initial state and the final state, respectively.

FIG. 20 shows an activation barrier.

FIGS. 21A and 21B show models in the initial state and the final state, respectively.

FIG. 22 shows an activation barrier.

FIG. 23 shows the transition levels of H_{O}.

FIG. 24 shows a calculation model.

FIG. 25 shows structures of a model in reaction paths.

FIG. 26 shows energy changes in reaction paths.

FIG. 27 shows a calculation model.

FIG. 28 shows structures of a model in reaction paths.

FIG. 29 shows energy changes in reaction paths.

FIGS. 30A to 30D are cross-sectional views and circuit diagrams illustrating one embodiment of a semiconductor device.

FIG. 31 is a cross-sectional view illustrating one embodiment of a semiconductor device.

FIGS. 32A and 32B are cross-sectional views each illustrating one embodiment of a semiconductor device.

FIGS. 33A to 33C are a cross-sectional view and circuit diagrams illustrating one embodiment of a semiconductor device.

FIG. 34 shows a structural example of an RF device tag of one embodiment.

FIG. 35 shows a structural example of a CPU of one embodiment.

FIG. 36 is a circuit diagram of a memory element of one embodiment.

FIGS. 37A to 37C are a top view, a cross-sectional view, and a circuit diagram of a display device of one embodiment.

FIGS. 38A and 38B are a circuit diagram and a cross-sectional view of a display device of one embodiment.

FIGS. 39A to 39F illustrate electronic devices of an embodiment.

FIGS. 40A to 40F illustrate application examples of an RF device of one embodiment.

### DETAILED DESCRIPTION OF THE INVENTION

Embodiments of the present invention will be described in detail with reference to the accompanying drawings. Note that the present invention is not limited to the description below, and it is easily understood by those skilled in the art that modes and details can be modified in various ways. Therefore, the present invention is not construed as being limited to description of the embodiments. In the description of the structures of the present invention with reference to the drawings, the same reference numerals are used in common for the same portions in different drawings. Note that the same hatch pattern is applied to similar parts, and the similar parts are not especially denoted by reference numerals in some cases.

Note that the size, the thickness of films (layers), or regions in drawings is sometimes exaggerated for simplicity.

In this specification, the terms “film” and “layer” can be interchanged with each other.

A voltage usually refers to a potential difference between a given potential and a reference potential (e.g., a source potential or a ground potential (GND)). A voltage can be referred to as a potential and vice versa.

Note that the ordinal numbers such as “first” and “second” in this specification are used for convenience and do not denote the order of steps or the stacking order of layers. Therefore, for example, the term “first” can be replaced with the term “second”, “third”, or the like as appropriate. In addition, the ordinal numbers in this specification and the like do not correspond to the ordinal numbers which specify one embodiment of the present invention in some cases.

Note that a “semiconductor” includes characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Further, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor. For example, an element with a concentration lower than 0.1 atomic % is an impurity. When an impurity is contained, the density of states (DOS) may be formed in a semiconductor, the carrier mobility may be decreased, or the crystallinity may be decreased, for example. In the case where the semiconductor is an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. In the case of an oxide semiconductor, oxygen vacancy may be formed by entry of impurities such as hydrogen. Furthermore, when the semiconductor layer is silicon, examples of an impurity which changes the characteristics of the semiconductor include oxygen, Group 1 elements except hydrogen, Group 2 elements, Group 13 elements, and Group 15 elements.

In this specification, the phrase “A has a region with a concentration B” includes, for example, “the concentration of the entire region in a region of A in the depth direction is B”, “the average concentration in a region of A in the depth direction is B”, “the median value of a concentration in a region of A in the depth direction is B”, “the maximum value of a concentration in a region of A in the depth direction is B”, “the minimum value of a concentration in a region of A in the depth direction is B”, “a convergence value of a concentration in a region of A in the depth direction is B”, and “a concentration in a region of A in which a probable value is obtained in measurement is B”.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

A channel width refers to, for example, the length of a portion where a source and a drain face each other in a region where a semiconductor (or a portion where a current flows in a semiconductor when a transistor is on) and a gate electrode overlap with each other, or a region where a channel is formed in a top view. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on transistor structures, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is high in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known as an assumption condition. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Further, in this specification, in the case where the term “channel width” is simply used, it may denote a surrounded channel width and an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where electric field mobility, a current value per channel width, and the like of a transistor are obtained by calculation, a surrounded channel width may be used for the calculation. In that case, a value different from one in the case where an effective channel width is used for the calculation is obtained in some cases.

Note that in this specification, the description “A has a shape such that an end portion extends beyond an end portion of B” may indicate, for example, the case where at least one of end portions of A is positioned on an outer side than at least one of end portions of B in a top view or a cross-sectional view. Thus, the description “A has a shape such that an end portion extends beyond an end portion of B” can be alternately referred to as the description “one of end portions of A is positioned on an outer side than one of end portions of B in a top view”, for example.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly also includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

### Embodiment 1

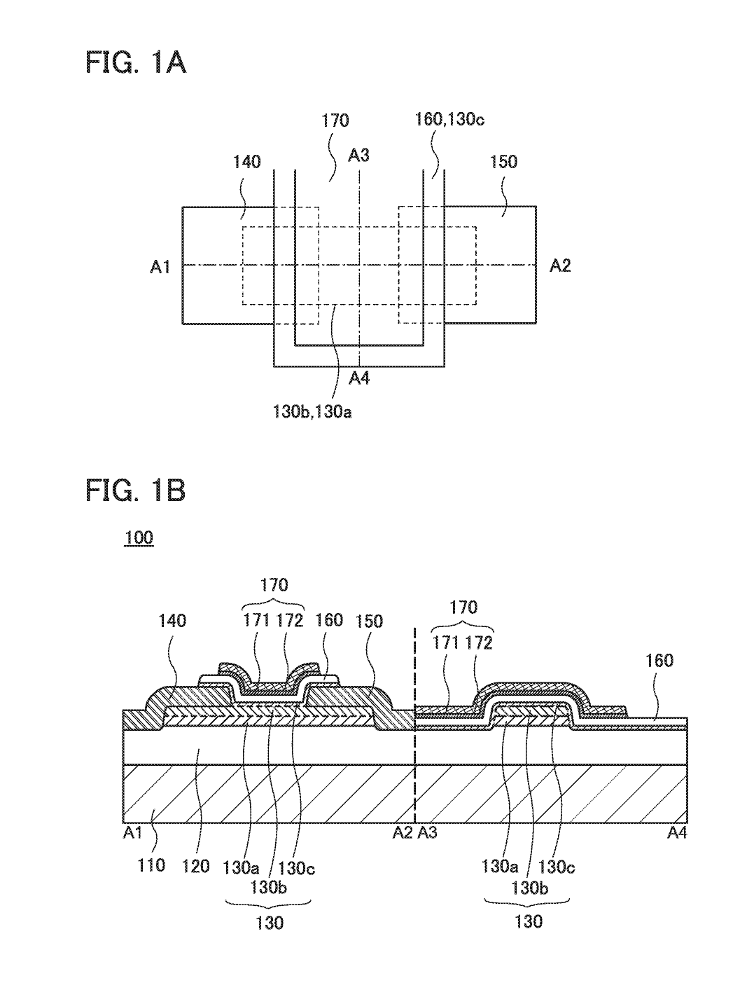

In this embodiment, a semiconductor device of one embodiment of the present invention is described with reference to FIGS. 1A and 1B, FIGS. 2A and 2B, and FIGS. 3A and 3B. Described in this embodiment are structures and manufacturing methods of an oxide semiconductor film having conductivity and a conductive film in contact with the oxide semiconductor film having conductivity. Note that here, the oxide semiconductor film having conductivity serves as an electrode or a wiring.

### <Components of Transistor Structure 1>

Examples of components of the transistor illustrated in FIGS. 1A and 1B are described below.

As the substrate 110, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a single material semiconductor substrate of silicon, germanium, or the like or a compound semiconductor substrate of silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 110. As a method for providing the transistor over a flexible substrate, there is a method in which the transistor is formed over a non-flexible substrate and then the transistor is separated and transferred to the substrate 110 which is a flexible substrate. In that case, a separation layer is preferably provided between the non-flexible substrate and the transistor. As the substrate 110, a sheet containing a fiber, a film, or a foil may be used. The substrate 110 may have elasticity. The substrate 110 may have a property of returning to its original shape when bending or pulling is stopped. Alternatively, the substrate 110 may have a property of not returning to its original shape. The thickness of the substrate 110 is, for example, greater than or equal to 5 μm and less than or equal to 700 μm, preferably greater than or equal to 10 μm and less than or equal to 500 μm, or further preferably greater than or equal to 15 μm and less than or equal to 300 When the substrate 110 has a small thickness, the weight of the semiconductor device can be reduced. When the substrate 110 has a small thickness, even in the case of using glass or the like, the substrate 110 may have elasticity or a property of returning to its original shape when bending or pulling is stopped. Therefore, an impact applied to the semiconductor device over the substrate 110, which is caused by dropping or the like, can be reduced. That is, a durable semiconductor device can be provided.

For the substrate 110 which is a flexible substrate, metal, an alloy, resin, glass, or fiber thereof can be used, for example. The flexible substrate 110 preferably has a lower coefficient of linear expansion because deformation due to an environment is suppressed. The flexible substrate 110 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, acrylic, and polytetrafluoroethylene (PTFE). In particular, aramid is preferably used for the flexible substrate 110 because of its low coefficient of linear expansion.

The insulator 120 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 120 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 120 may have a function of preventing diffusion of impurities from the substrate 110. In the case where a semiconductor 130 is an oxide semiconductor, the insulator 120 can have a function of supplying oxygen to the semiconductor 130. Therefore, the insulator 120 is preferably an insulator containing excess oxygen.

The insulator containing excess oxygen means an insulator from which oxygen is released by heat treatment, for example. The silicon oxide layer containing excess oxygen means a silicon oxide layer which can release oxygen by heat treatment or the like, for example. Therefore, the insulator 120 is an insulator in which oxygen can be moved. In other words, the insulator 120 may be an insulator having an oxygen-transmitting property. For example, the insulator 120 may be an insulator having a higher oxygen-transmitting property than the semiconductor 130.

The insulator containing excess oxygen has a function of reducing oxygen vacancies in the semiconductor 130 in some cases. Such oxygen vacancies form deep states in the semiconductor 130 and serve as hole traps or the like. In addition, hydrogen comes into the site of such an oxygen vacancy and forms an electron serving as a carrier. Therefore, by reducing the oxygen vacancies in the semiconductor 130, the transistor can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in thermal desorption spectroscopy (TDS) analysis in the range of a surface temperature of 100° C. to 700° C. or 100° C. to 500° C.

Here, the method of measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Further, an oxygen molecule including an oxygen atom having a mass number of 17 or 18 which is an isotope of an oxygen atom is also not taken into consideration because the proportion of such a molecule in the natural world is minimal.

$${N}_{O 2} = \frac{{N}_{H 2}}{{S}_{H 2}} \times {S}_{O 2} \times α \qquad [ Formula 1 ]$$

The value N_{H2} is obtained by conversion of the amount of hydrogen molecules desorbed from the standard sample into densities. The value S_{H2} is the integral value of ion intensity in the case where the standard sample is subjected to the TDS analysis. Here, the reference value of the standard sample is set to N_{H2}/S_{H2}. S_{O2} is the integral value of ion intensity when the measurement sample is analyzed by TDS. The value a is a coefficient affecting the ion intensity in the TDS analysis. Refer to Japanese Published Patent Application No. H6-275697 for details of the above formula. The amount of released oxygen was measured with a thermal desorption spectroscopy apparatus produced by ESCO Ltd., EMD-WA1000S/W using a silicon substrate containing hydrogen atoms at 1×10¹⁶ atoms/cm² as the reference sample.

Further, in the TDS analysis, oxygen is partly detected as an oxygen atom. The ratio between oxygen molecules and oxygen atoms can be calculated from the ionization rate of the oxygen molecules. Note that, since the above a includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in ESR.

The insulator containing excess oxygen may be formed using oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

As the semiconductor 130, an oxide semiconductor including a crystal is used. In FIGS. 1A and 1B, the semiconductor 130 is a stacked-layer film in which a first semiconductor 130a, a second semiconductor 130b, and a third semiconductor 130c are stacked in this order. A semiconductor which can be used as the semiconductor 130 is described below.

The semiconductor 130 is an oxide semiconductor containing indium, for example. The semiconductor 130 can have high carrier mobility (electron mobility) by containing indium, for example. The semiconductor 130 preferably contains an element M. The element M is preferably aluminum, gallium, yttrium, tin, or the like. Other elements which can be used as the element M are boron, silicon, titanium, iron, nickel, germanium, zirconium, molybdenum, lanthanum, cerium, neodymium, hafnium, tantalum, tungsten, and the like. Note that two or more of the above elements may be used in combination as the element M. The element M is an element having a high bonding energy with oxygen, for example. The element M is an element whose bonding energy with oxygen is higher than that of indium. The element M is an element that can increase the energy gap of the oxide semiconductor, for example. Furthermore, the semiconductor 130 preferably contains zinc. When the oxide semiconductor contains zinc, the oxide semiconductor is easily to be crystallized, for example.

Note that the semiconductor 130 is not limited to the oxide semiconductor containing indium. The semiconductor 130 may be, for example, an oxide semiconductor which does not contain indium and contains zinc, an oxide semiconductor which does not contain indium and contains gallium, or an oxide semiconductor which does not contain indium and contains tin, e.g., a zinc tin oxide, a gallium tin oxide, or gallium oxide.

The first semiconductor 130a, the second semiconductor 130b, and the third semiconductor 130c preferably include indium. In the case of using an In-M-Zn oxide as the first semiconductor 130a, when a summation of In and M is assumed to be 100 atomic %, the proportions of In and M are preferably set to be less than 50 atomic % and greater than 50 atomic %, respectively, further preferably less than 25 atomic % and greater than 75 atomic %, respectively. In the case of using an In-M-Zn oxide as the second semiconductor 130b, when the summation of In and M is assumed to be 100 atomic %, the proportions of In and M are preferably set to be greater than 25 atomic % and less than 75 atomic %, respectively, further preferably greater than 34 atomic % and less than 66 atomic %, respectively. In the case of using an In-M-Zn oxide as the third semiconductor 130c, when the summation of In and M is assumed to be 100 atomic %, the proportions of In and M are preferably set to be less than 50 atomic % and greater than 50 atomic %, respectively, further preferably less than 25 atomic % and greater than 75 atomic %, respectively. Note that the third semiconductor 130c may be an oxide that is a type the same as that of the first semiconductor 130a.

As the second semiconductor 130b, an oxide having an electron affinity higher than those of the first semiconductor 130a and the third semiconductor 130c is used. For example, as the second semiconductor 130b, an oxide having an electron affinity higher than those of the first semiconductor 130a and the third semiconductor 130c by 0.07 eV or higher and 1.3 eV or lower, preferably 0.1 eV or higher and 0.7 eV or lower, further preferably 0.15 eV or higher and 0.4 eV or lower is used. Note that the electron affinity refers to an energy gap between the vacuum level and the bottom of the conduction band.

An indium gallium oxide has a small electron affinity and a high oxygen-blocking property. Therefore, the third semiconductor 130c preferably includes indium gallium oxide. The gallium atomic ratio [Ga/(In+Ga)] is, for example, higher than or equal to 70%, preferably higher than or equal to 80%, more preferably higher than or equal to 90%.

Note that the first semiconductor 130a and/or the third semiconductor 130c may be gallium oxide. For example, when gallium oxide is used for the third semiconductor 130c, a leakage current generated between the conductor 170 and the conductor 140 or 150 can be reduced. In other words, the off-state current of the transistor can be reduced.

At this time, when a gate voltage is applied, a channel is formed in the second semiconductor 130b, which has the largest electron affinity among the first semiconductor 130a, the second semiconductor 130b, and the third semiconductor 130c. The channel may be formed in two or three layers selected from the first semiconductor 130a, the second semiconductor 130b, and the third semiconductor 130c.

Note that the thickness of the third semiconductor 130c is preferably as small as possible to increase the on-state current of the transistor. The third semiconductor 130c preferably has a region with a thickness of less than 10 nm, preferably less than or equal to 5 nm, more preferably less than or equal to 3 nm, for example. Meanwhile, the third semiconductor 130c has a function of blocking elements other than oxygen (such as hydrogen and silicon) included in the adjacent insulator from entering the second semiconductor 130b where a channel is formed. For this reason, it is preferable that the third semiconductor 130c have a certain thickness. For example, the third semiconductor 130c is formed to include a region having a thickness of greater than or equal to 0.3 nm, preferably greater than or equal to 1 nm, more preferably greater than or equal to 2 nm. Moreover, the third semiconductor 130c preferably has an oxygen blocking property to inhibit outward diffusion of oxygen released from the insulator 120 and the like.

To improve reliability, it is preferable that the thickness of the first semiconductor 130a be large and the thickness of the third semiconductor 130c be small. For example, the first semiconductor 130a may include a region with a thickness of greater than or equal to 10 nm, preferably greater than or equal to 20 nm, further preferably greater than or equal to 40 nm, and still further preferably greater than or equal to 60 nm. When the thickness of the first semiconductor 130a is made large, a distance from an interface between the adjacent insulator and the first semiconductor 130a to the second semiconductor 130c where the channel is formed can be large. Since the productivity of the semiconductor device including the transistor might be decreased, the first semiconductor 130a has a region with a thickness, for example, less than or equal to 200 nm, preferably less than or equal to 120 nm, or further preferably less than or equal to 80 nm.

For example, silicon in the oxide semiconductor might serve as a carrier trap or a carrier generation source. Therefore, the silicon concentration of the second semiconductor 130b is preferably as low as possible. For example, a region with a silicon concentration of lower than 1×10¹⁹ atoms/cm³, preferably lower than 5×10¹⁸ atoms/cm³, or further preferably lower than 2×10¹⁸ atoms/cm³ which is measured by secondary ion mass spectrometry (SIMS) is provided between the second semiconductor 130b and first semiconductor 130c. A region with a silicon concentration of lower than 1×10¹⁹ atoms/cm³, preferably lower than 5×10¹⁸ atoms/cm³, more preferably lower than 2×10¹⁸ atoms/cm³ which is measured by SIMS is provided between the second semiconductor 130b and the third semiconductor 130c.

When hydrogen contained in the second semiconductor 130b as an impurity moves to the surface of the semiconductor, the hydrogen bonds to oxygen in the vicinity of the surface to form a water molecule, which is released from the surface in some cases. At this time, an oxygen vacancy Vₒ is formed in a portion from which O is released as a water molecule. For that reason, it is preferable that the hydrogen concentration of the second semiconductor 130b be sufficiently reduced. Therefore, the amount of molecules released from the second semiconductor 130b detected by TDS analysis (converted into the number of water molecules) is less than or equal to 1.0×10²¹/cm³ (1.0/nm³), preferably less than or equal to 1.0×10²⁰/cm³ (0.1/nm³) in the TDS analysis (converted into the number of water molecules) at a substrate surface temperature raging from 100° C. to 700° C. or 100° C. to 500° C., is used.

For example, the number of water molecules (N_{H2O}) released from a measurement sample can be calculated in a manner similar to that of the above oxygen molecules, using the TDS results of a silicon substrate containing hydrogen at a predetermined density, which is a reference sample, and the TDS results of the measurement sample. Here, all gases having a mass-to-charge ratio of 18 obtained in the TDS analysis are assumed to originate from a water molecule. Note that CH₄, which is a gas having the mass-to-charge ratio of 18, is not taken into consideration because it is unlikely to be present. Further, an oxygen molecule including an oxygen atom having a mass number of 17 or 18 which is an isotope of an oxygen atom is also not taken into consideration because the proportion of such a molecule in the natural world is minimal.

Note that it is difficult for hydrogen as an impurity in the semiconductor to exist as a water molecule because the hydrogen is in a state of a hydrogen atom, a hydrogen ion, a hydrogen molecule, a hydroxy group, a hydroxide ion, and the like in the semiconductor.

To reduce the hydrogen concentration of the second semiconductor 130b, the hydrogen concentrations of the first semiconductor 130a and the third semiconductor 130c are preferably reduced. Thus, the first semiconductor 130a and the third semiconductor 130c may release water molecules measured by TDS analysis (converted into the number of water molecules) of less than or equal to 1.0×10²¹/cm³ (1.0/nm³), preferably less than or equal to 1.0×10²⁰/cm³ (0.1/nm³) at a substrate surface temperature raging from 100° C. to 700° C. or 100° C. to 500° C.

By using an oxide semiconductor including a crystal whose hydrogen concentration is sufficiently lowered for a channel formation region in a transistor, the transistor can have stable electric characteristics. That is, a change in electrical characteristics can be inhibited and reliability can be improved. Further, a semiconductor device with low power consumption can be provided.

To reduce the nitrogen concentration of the second semiconductor 130b, the nitrogen concentrations of the first semiconductor 130a and the third semiconductor 130c are preferably reduced. The first semiconductor 130a and the third semiconductor 130c each have a region in which the nitrogen concentration measured by SIMS is lower than or equal to 5×10¹⁹ atoms/cm³, preferably less than or equal to 5×10¹⁸ atoms/cm³, further preferably less than or equal to 1×10¹⁸ atoms/cm³, still more preferably less than or equal to 5×10¹⁷ atoms/cm³.

Note that when copper enters the oxide semiconductor, an electron trap might be generated. The electron trap might shift the threshold voltage of the transistor in the positive direction. Therefore, the copper concentration on the surface of or in the second semiconductor 130b is preferably as low as possible. For example, the second semiconductor 130b preferably has a region in which the copper concentration is lower than or equal to 1×10¹⁹ atoms/cm³, lower than or equal to 5×10¹⁸ atoms/cm³, or lower than or equal to 1×10¹⁸ atoms/cm³.

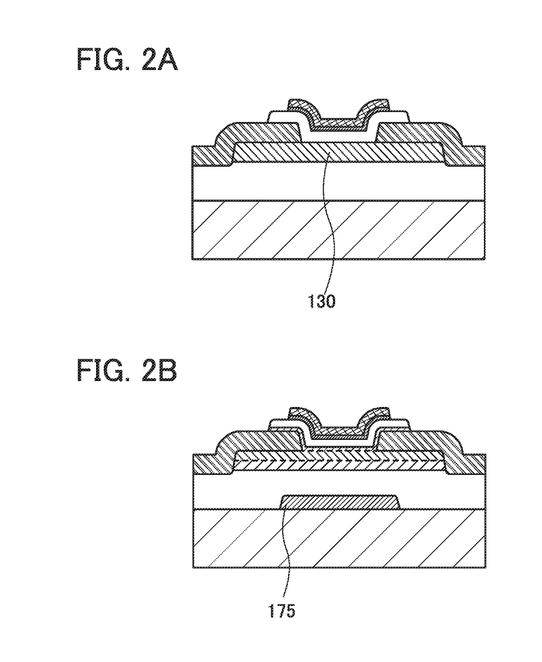

Note that the above-described three-layer structure is an example. For example, a single layer may be used instead of a stacked layer structure as illustrated in FIG. 2A. For example, a two-layer structure without the first or third semiconductor layer may be employed. A four-layer structure may be employed, in which any one of the semiconductors described as examples of the first to third semiconductors is provided below or over the first semiconductor or below or over the third semiconductor. Alternatively, an n-layer structure (n is an integer of 5 or more) may be employed, in which one or more of the semiconductors described as the examples of the first to third semiconductors are provided in two or more of the following positions: over the first semiconductor; below the first semiconductor; over the third semiconductor; and below the third semiconductor.

Each of the conductors 140 and 150 may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy film or a compound film of the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 160 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 160 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The conductor 170 may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy film or a compound film of the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

### <Modification Example of Transistor Structure 1>

The transistor of one embodiment of the present invention may include a conductor 175 between the substrate 110 and the insulator 120 as illustrated in FIG. 2B. The conductor 175 serves as a second gate electrode (also referred to as a back gate electrode) of the transistor.

For example, a voltage which is the same as that applied to the conductor 170 can be applied to the conductor 175. Thus, an electric field can be applied from upper and lower sides of the semiconductor 130, resulting in increased on-state current of the transistor. In addition, the off-state current of the transistor can be reduced. For example, by applying a lower voltage or a higher voltage than a source electrode to the conductor 175, the threshold voltage of the transistor may be shifted in the positive direction or the negative direction. For example, by shifting the threshold voltage of the transistor in the positive direction, a normally-off transistor in which the transistor is in a non-conduction state (off state) even when the gate voltage is 0 V can be achieved in some cases. The voltage applied to the conductor 175 may be variable or fixed. When the voltage applied to the conductor 175 is a variable, a circuit for controlling the voltage may be electrically connected to the conductor 175.

The conductor 175 may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy film or a compound film of the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

### <Transistor Structure 2>

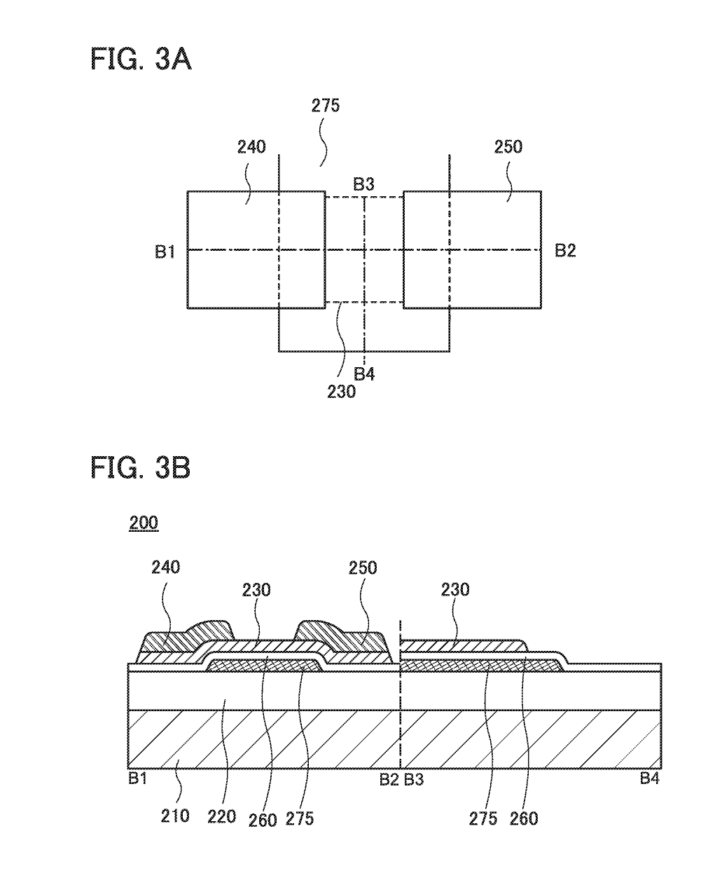

FIGS. 3A and 3B are a top view and a cross-sectional view of a transistor 200 of one embodiment of the present invention. FIG. 3A is a top view and FIG. 3B is a cross-sectional view taken along dashed-dotted line B1-B2 and dashed-dotted line B3-B4 in FIG. 3A. Note that for simplification of the drawing, some components in the top view in FIG. 3A are not illustrated.

The transistor 200 illustrated in FIGS. 3A and 3B includes an insulator 220 over a substrate 210, a conductor 275 over the insulator 220, an insulator 260 over the conductor 275, a semiconductor 230 over the insulator 260, and a conductor 240 and a conductor 250 which are spaced apart and are in contact with the top surface of the semiconductor 230. Note that the conductor 275 includes a region over which the semiconductor 230 is positioned with the insulator 260 provided therebetween. Note that the insulator 220 provided between the substrate 210 and the conductor 275 is not necessarily provided.

The semiconductor 230 serves as a channel formation region of the transistor 200. The conductor 275 serves as a first gate electrode (also referred to as a front gate electrode) of the transistor 200. The insulator 260 serves as a gate insulator of the transistor 200. The conductor 240 and the conductor 250 have functions of the source electrode and the drain electrode of the transistor.

The insulator 260 is preferably an insulator containing excess oxygen.

For the substrate 210, the description of the substrate 110 is referred to. For the conductor 275, the description of the conductor 170 is referred to. For the insulator 260, the description of the insulator 160 is referred to. For the semiconductor 230, the description of the semiconductor 130 is referred to. For the conductor 240 and the conductor 250, the description of the conductor 140 and the conductor 150 is referred to. For the insulator 220, the description of the insulator 120 is referred to.

Furthermore, this embodiment can be applied to a transistor of various types. Depending on circumstances or conditions, the transistors each can be a planar-type transistor, a fin-type transistor, or a tri-gate transistor, for example. In addition, the transistor of one embodiment of the present invention can also be applied to a transistor having a structure in which a gate electrode electrically surrounds a semiconductor in the channel width direction with a gate insulator interposed therebetween (surrounded channel (s-channel) structure). With an s-channel structure, a transistor having high on-state current can be obtained.

### Embodiment 2

### Structure of Oxide Semiconductor

The structure of an oxide semiconductor is described below.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Note that an a-like OS has a periodic structure in a microscopic region, but at the same time has a void and has an unstable structure. For this reason, an a-like OS has physical properties similar to those of an amorphous oxide semiconductor.

### <CAAC-OS>

First, a CAAC-OS is described.

A CAAC-OS is an oxide semiconductor having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

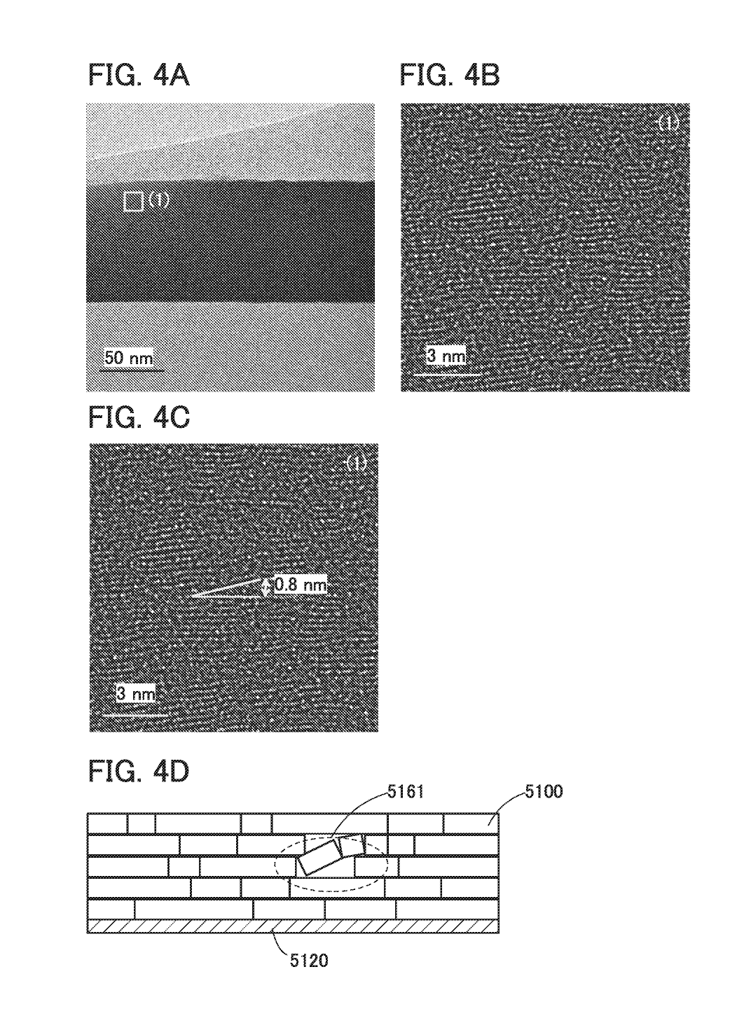

A CAAC-OS observed with TEM is described below. FIG. 4A shows a high-resolution TEM image of a cross section of the CAAC-OS observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 4B is an enlarged Cs-corrected high-resolution TEM image of a region (1) in FIG. 4A. FIG. 4B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 4B, the CAAC-OS film has a characteristic atomic arrangement. The characteristic atomic arrangement is denoted by an auxiliary line in FIG. 4C. FIGS. 4B and 4C prove that the size of a pellet is approximately 1 nm to 3 nm, and the size of a space caused by tilt of the pellets is approximately 0.8 nm. Therefore, the pellet can also be referred to as a nanocrystal (nc). Furthermore, the CAAC-OS can also be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 4D). The part in which the pellets are tilted as observed in FIG. 4C corresponds to a region 5161 shown in FIG. 4D.

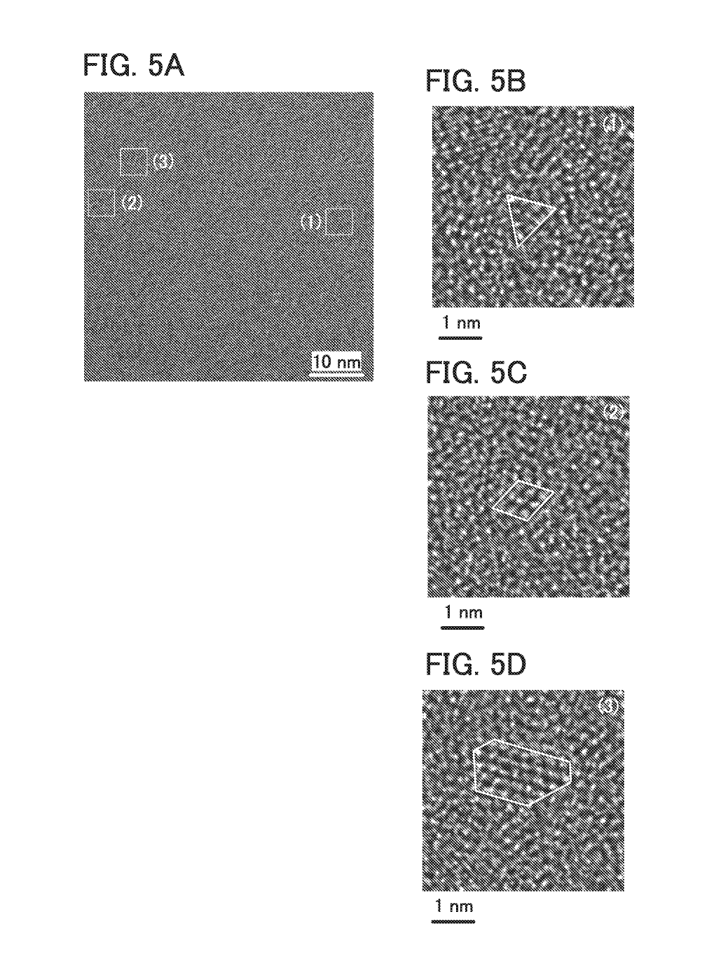

FIG. 5A shows a Cs-corrected high-resolution TEM image of a plane of the CAAC-OS observed from a direction substantially perpendicular to the sample surface. FIGS. 5B, 5C, and 5D are enlarged Cs-corrected high-resolution TEM images of regions (1), (2), and (3) in FIG. 5A, respectively. FIGS. 5B, 5C, and 5D indicate that metal atoms are arranged in a triangular, quadrangular, or hexagonal configuration in a pellet. However, there is no regularity of arrangement of metal atoms between different pellets.

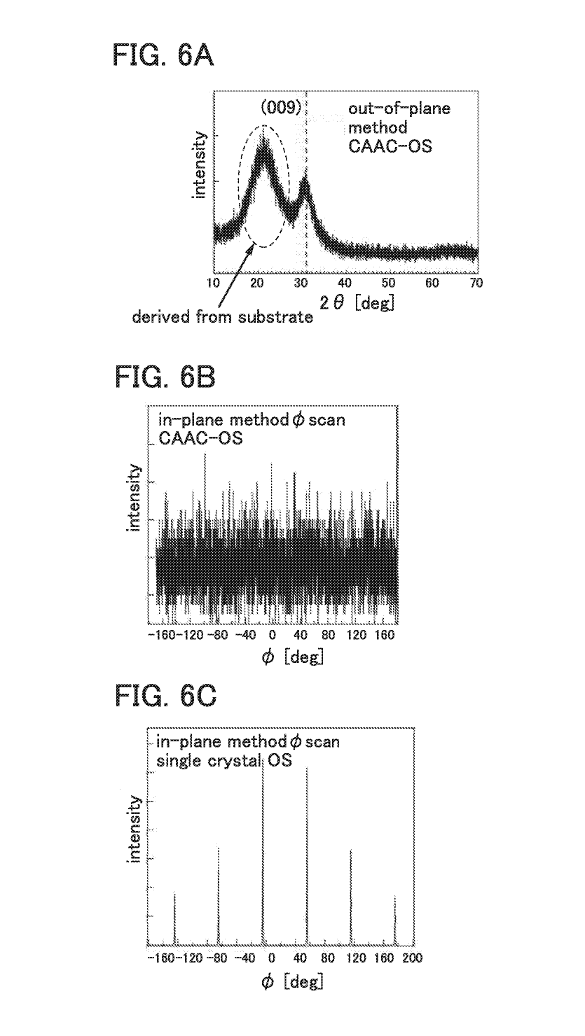

Next, a CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 6A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2θ of around 31°. The peak at 2θ of around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is attributed to the (110) plane of the InGaZnO₄ crystal. In the case of the CAAC-OS, when analysis (φ scan) is performed with 2θ fixed at around 56° and with the sample rotated using a normal vector of the sample surface as an axis (φ axis), as shown in FIG. 6B, a peak is not clearly observed. In contrast, in the case of a single crystal oxide semiconductor of InGaZnO₄, when φ scan is performed with 2θ fixed at around 56°, as shown in FIG. 6C, six peaks which are derived from crystal planes equivalent to the (110) plane are observed. Accordingly, the structural analysis using XRD shows that the directions of a-axes and b-axes are irregularly oriented in the CAAC-OS.

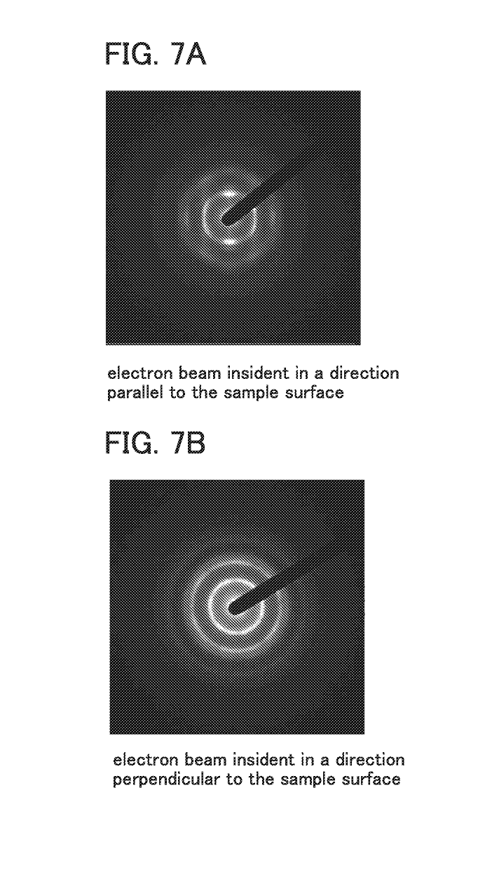

Next, a CAAC-OS analyzed by electron diffraction is described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 7A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 7B shows a diffraction pattern obtained in such a manner that an electron beam with a probe diameter of 300 nm is incident on the same sample in a direction perpendicular to the sample surface. As shown in FIG. 7B, a ring-like diffraction pattern is observed. Thus, the electron diffraction also indicates that the a-axes and b-axes of the pellets included in the CAAC-OS do not have regular alignment. The first ring in FIG. 7B is considered to be derived from the (010) plane, the (100) plane, and the like of the InGaZnO₄ crystal. The second ring in FIG. 7B is considered to be derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. Furthermore, oxygen vacancies in the oxide semiconductor serve as carrier traps or serve as carrier generation sources when hydrogen is captured therein.

The CAAC-OS having small amounts of impurities and oxygen vacancies is an oxide semiconductor with low carrier density. Specifically, an oxide semiconductor with a carrier density of lower than 8×10¹¹/cm³, preferably lower than 1×10¹¹/cm³, further preferably lower than 1×10¹⁰/cm³, and higher than or equal to 1×10⁻⁹/cm³ can be used. Such an oxide semiconductor is referred to as a highly purified intrinsic or substantially highly purified intrinsic oxide semiconductor. CAAC-OS has a low impurity concentration and a low density of defect states. Thus, the CAAC-OS can be referred to as an oxide semiconductor film having stable characteristics.

<nc-OS>

Next, an nc-OS is described.

An nc-OS has a region in which a crystal part is observed and a region in which a crystal part is not clearly observed in a high-resolution TEM image. In most cases, the size of a crystal part included in the nc-OS is greater than or equal to 1 nm and less than or equal to 10 nm, or greater than or equal to 1 nm and less than or equal to 3 nm. Note that an oxide semiconductor including a crystal part with a size greater than or equal to 10 nm and less than or equal to 100 nm is referred to as a microcrystalline oxide semiconductor in some cases. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not ordered. Accordingly, the nc-OS cannot be distinguished from an a-like OS and an amorphous oxide semiconductor, depending on an analysis method. For example, when the nc-OS is analyzed by an out-of-plane method using an X-ray beam having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet. Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots are shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an a-like OS or an amorphous oxide semiconductor. Note that there is no regularity of crystal orientation between different pellets in the nc-OS. Therefore, the nc-OS has a higher density of defect states than the CAAC-OS.

<a-like OS>

An a-like OS has a structure intermediate between those of the nc-OS and the amorphous oxide semiconductor.

In a high-resolution TEM image of the a-like OS, a void may be observed. Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in structure caused by electron irradiation is described below.

An a-like OS (referred to as Sample A), an nc-OS (referred to as Sample B), and a CAAC-OS (referred to as Sample C) are prepared as samples subjected to electron irradiation. Each of the samples is an In—Ga—Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of an InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

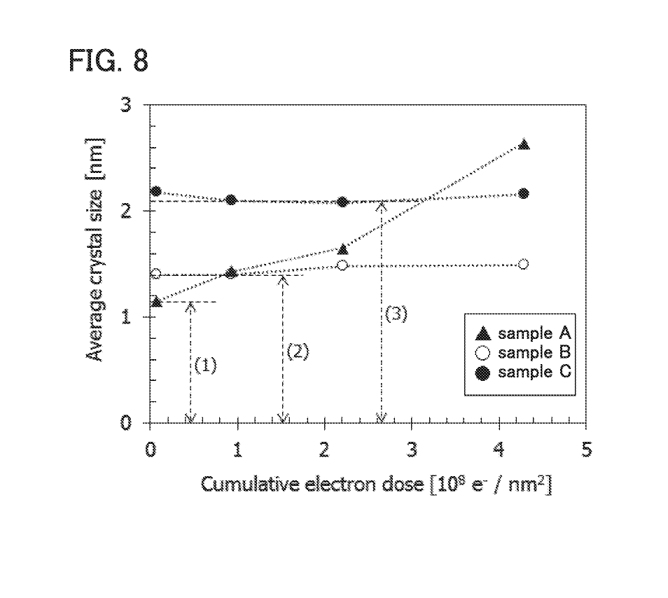

FIG. 8 shows change in the average size of crystal parts (at 22 points to 45 points) in each sample. Note that the crystal part size corresponds to the length of a lattice fringe. FIG. 8 indicates that the crystal part size in the a-like OS increases with an increase in the cumulative electron dose. Specifically, as shown by (1) in FIG. 8, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 8, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate the density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more films of an amorphous oxide semiconductor, an a-like OS, an nc-OS, and a CAAC-OS, for example.

### Embodiment 3

Described in this embodiment is the behavior of H and OH that are produced by decomposition of water (hereinafter referred to as H₂O) that has entered InGaZnO₄. Note that InGaZnO₄ is a typical oxide semiconductor.

<1. H₂O in InGaZnO₄>

First, to measure the effect of H₂O in InGaZnO₄, calculation was made of a model in which H₂O was added to InGaZnO₄. The specific calculation is as follows.

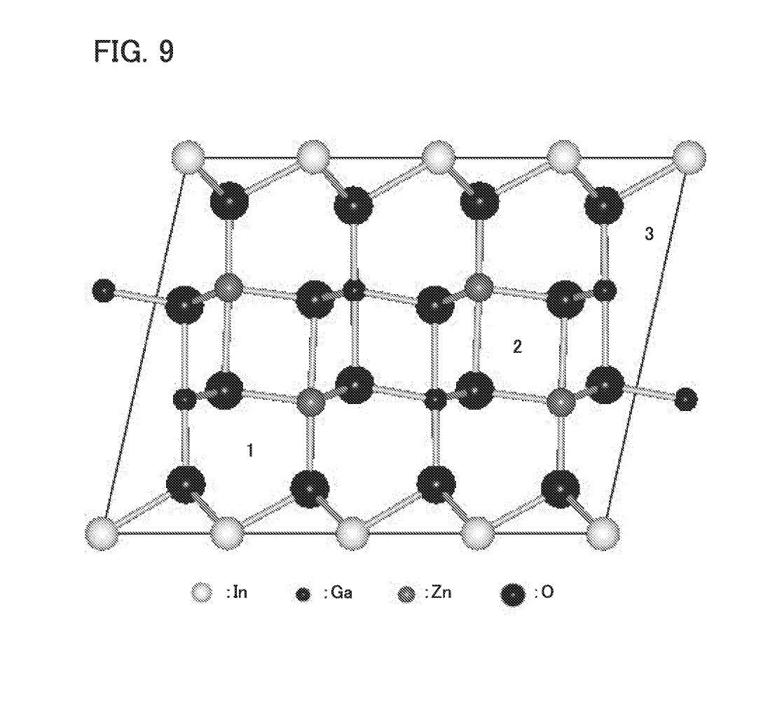

H₂O molecules were placed in an InGaZnO₄ crystal model (112 atoms) and a structure optimization calculation was performed. FIG. 9 shows a calculation model where 1, 2, and 3 represent the initial places of H₂O.

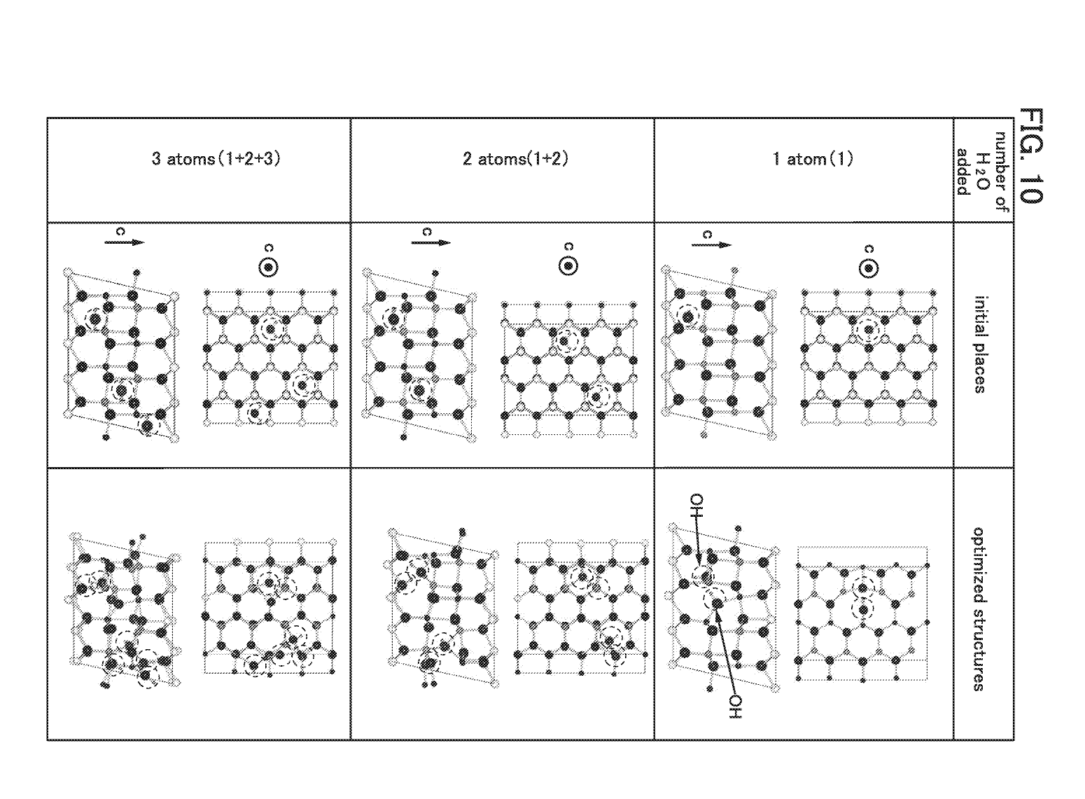

Table 1 shows the calculation conditions. FIG. 10 shows optimized structures of the model in which H₂O was added.

TABLE 1

| Software | VASP |
|---|---|
| Model | InGaZnO₄ crystal (112 atoms) + nH₂O (n = 1 to 3) |
| Calculation | Structure optimization (including lattice constant) |
| Functional | GGA/PBE |
| Cut-off energy | 500 eV |
| K points | 2 × 2 × 3 |

In either model, it is difficult for H₂O molecules to exist stably in InGaZnO₄, and H₂O in InGaZnO₄ was decomposed into H and OH.

That is, these results reveal that H₂O cannot exist in dense highly crystalline InGaZnO₄, or even when H₂O happens to exist, H₂O is decomposed. Note that if H₂O exists, the place can be an oxide semiconductor with low density (e.g., an a-like OS or an amorphous oxide semiconductor).

Next, H and OH in InGaZnO₄ will be described.

### <2. H in InGaZnO₄>

### <2-(1). Diffusion of H>

Here, the mobility of hydrogen in an InGaZnO₄ crystal was measured from the activation barrier along a hydrogen transfer path. Note that the two kinds of movement of hydrogen were assumed: hopping between oxygen atoms; and movement on one oxygen atom.

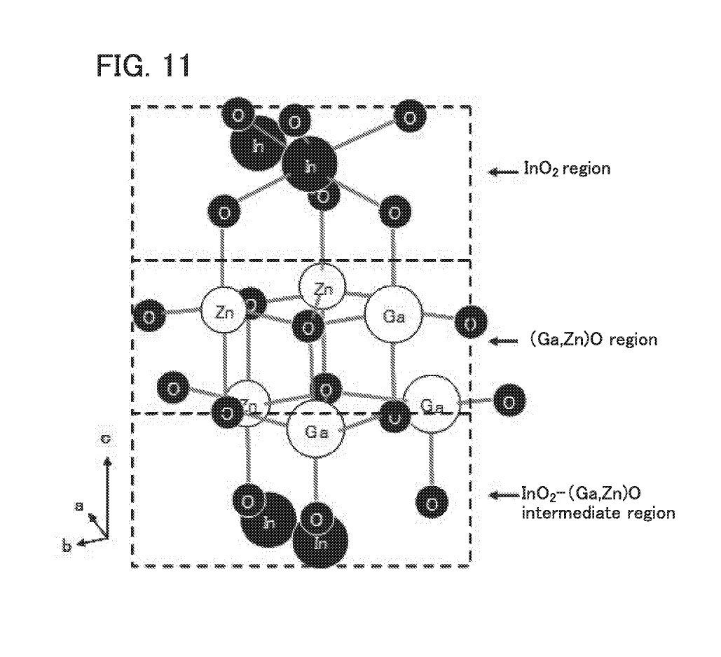

FIG. 11 is a schematic view showing different areas in a single crystal InGaZnO₄ (c-InGaZnO₄), in each of which the diffusion path of hydrogen was analyzed. The measurement was performed on the path in each of an InO₂ region, a (Ga, Zn)O region, and an InO₂—(Ga, Zn)O region (a-b plane direction), and the path crossing each region (c-axis direction).

The activation barrier was calculated by the first-principles electron state and molecular dynamics simulation using the Vienna ab initio simulation package (VASP). The nudged elastic band (NEB) method, which is to find a chemical reaction path, was also employed. The NEB method is a technique for determining the minimum energy path between given initial and final states.

### <<Intermediate Region Between InO₂ Layer and (Ga, Zn)O Layer>>

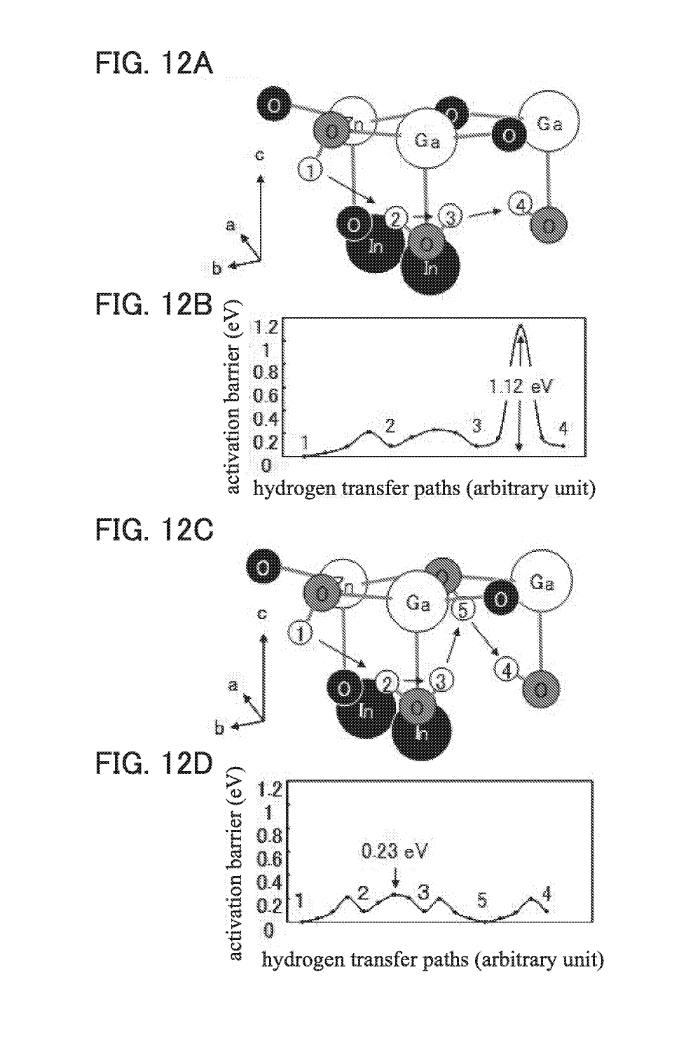

FIGS. 12A to 12D show hydrogen transfer paths in the region between the InO₂ layer and the (Ga, Zn)O layer, and activation barriers along the paths. Note that an energy of the most stable structure on the path was taken as the origin of energy. FIGS. 12A and 12C show the hydrogen transfer paths which are referred to as a path A and a path B, respectively. Note that numbers in FIGS. 12A to 12D represent the order of transfer of hydrogen. On the path A, hydrogen transfers from 3 to 4 directly, whereas on the path B, hydrogen transfers from 3 to 4 via 5.

FIG. 12B shows the calculation results of the activation barrier along the path A where hydrogen transfers from 1 to 4, and FIG. 12D shows the calculation results of the activation barrier along the path B where hydrogen transfers from 1 to 4 via 5.

The activation barrier shown in FIG. 12D is lower than that shown in FIG. 12B. Therefore, when hydrogen transfers from 3 to 4, the path B with a lower activation barrier is probably taken. In other words, when hydrogen transfers in the region between the InO₂ layer and the (Ga, Zn)O layer, the path B with a lower activation barrier will be taken.

### <<(Ga, Zn)O Region>>

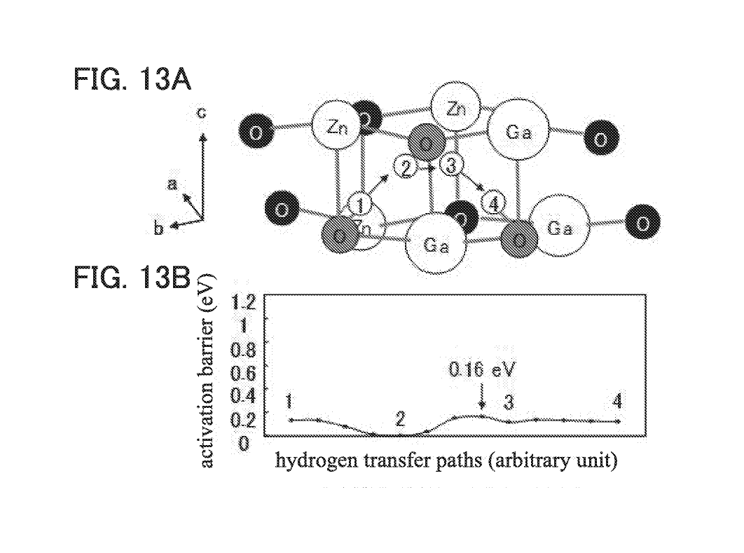

Next, a hydrogen transfer path in the (Ga, Zn)O region and the activation barrier along the path are shown in FIGS. 13A and 13B. Note that an energy of the most stable structure on the path was taken as the origin of energy. FIG. 13A shows the hydrogen transfer path in the (Ga, Zn)O region. The numbers in FIG. 13A represent the order of transfer of hydrogen. FIG. 13B shows the calculation results of the activation barrier along the path where hydrogen transfers from 1 to 4 in FIG. 13A.

FIG. 13B shows that the hydrogen path in the (Ga, Zn)O region has a low activation barrier of approximately 0.16 eV. Given only the height of the barrier, hydrogen will be more likely to transfer in the (Ga, Zn)O region than in the region between the InO₂ layer and the (Ga, Zn)O layer.

### <<InO₂ Region>>

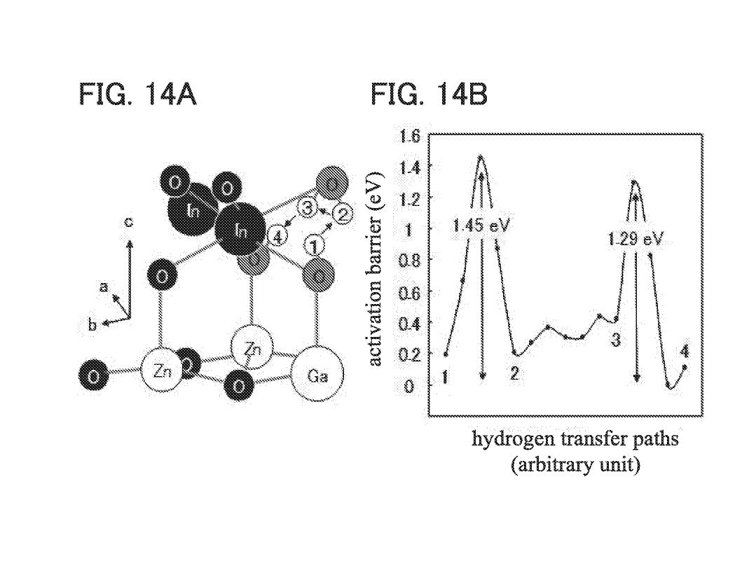

Next, a hydrogen transfer path in the InO₂ region and the activation barrier along the path are shown in FIGS. 14A and 14B. Note that an energy of the most stable structure on the path was taken as the origin of energy. FIG. 14A shows the hydrogen transfer path in the InO₂ region. The numbers in FIG. 14A represent the order of transfer of hydrogen. FIG. 14B shows the calculation results of the activation barrier along the path where hydrogen transfers from 1 to 4.

FIGS. 14A and 14B show that the activation barrier of the path in the InO₂ region is much higher than that in the other regions. Accordingly, hydrogen will be less likely to transfer in the InO₂ region than in the other regions.

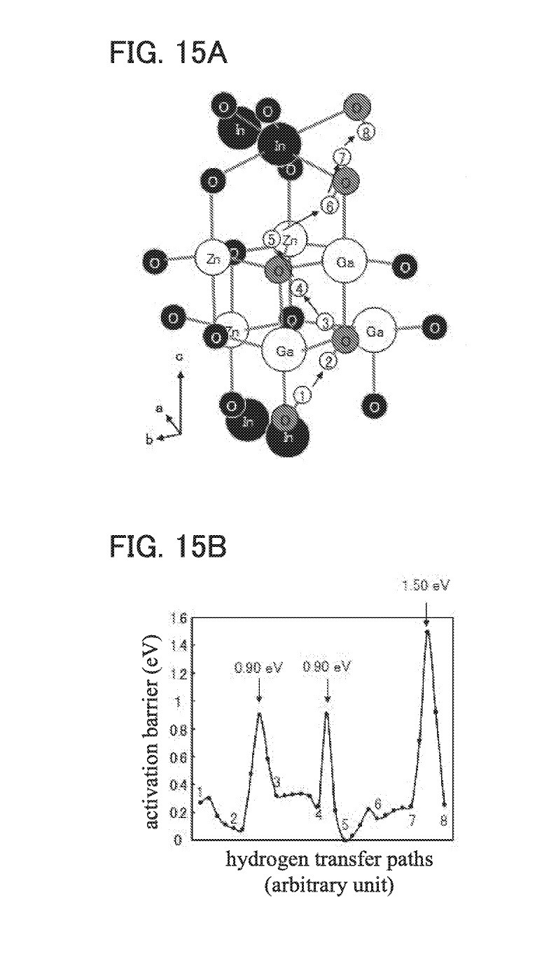

FIGS. 15A and 15B show a hydrogen transfer path in the c-axis direction and the activation barrier along the path. Note that an energy of the most stable structure on the path was taken as the origin of energy. FIG. 15A shows the hydrogen transfer path in the c-axis direction. The numbers in FIG. 15A represent the order of transfer of hydrogen. FIG. 15B shows the calculation results of the activation barrier along the path where hydrogen transfers from 1 to 8.

FIGS. 15A and 15B show that a high activation barrier exists on the way in and out of the (Ga, Zn)O region. This is probably because the hydrogen transfer path blocks M (metal)-O bond. A high activation barrier is found to exist also when hydrogen diffuses in the InO₂ region. Hence, hydrogen will be less likely to transfer continuously in the c-axis direction. Note that a cause of the high activation barrier might be a large radius of an In ion.

From the activation barriers obtained by calculation and the following Formula 2, reaction frequency (Γ) was calculated.

$$Γ = v exp ( - \frac{{E}_{a}}{{k}_{B} T} ) \qquad [ Formula 2 ]$$

In the formula, Eₐ represents the maximum activation barrier along the path; k_{B}, the Boltzmann constant; T, the absolute temperature; and v, the frequency factor.

Lastly, Table 2 shows the movement frequency that is estimated from the maximum barrier height of each path.

TABLE 2

| | | Maximum | | |
|---|---|---|---|---|
| | | barrier | Movement frequency | |
| | | height | 450° C. | 27° C. |
| Path | | (eV) | (s⁻¹) | (s⁻¹) |
| Region between InO₂ layer | A | 1.12 | 1.6 × 10⁵ | 1.0 × 10⁻⁶ |
| and (Ga, Zn)O₂ layer | | | | |
| (a-b plane direction) | | | | |
| Region between InO₂ layer | B | 0.23 | 2.5 × 10¹¹ | 1.4 × 10⁹ |
| and (Ga, Zn)O₂ layer | | | | |
| (a-b plane direction) | | | | |

| | | | |
|---|---|---|---|
| (Ga, Zn)O₂ layer | 0.16 | 7.7 × 10¹¹ | 2.1 × 10¹⁰ |
| (a-b plane direction) | | | |
| InO₂ layer | 1.45 | 8.0 × 10² | 4.6 × 10⁻¹² |
| (c-axis direction) | | | |
| Path into (out of) | 0.9 | 5.4 × 10⁶ | 7.8 × 10⁻³ |
| (Ga, Zn)O₂ layer | | | |
| (c-axis direction) | | | |

At temperatures of 27° C. and 450° C., the movement frequency was the highest in the region between the InO₂ layer and the (Ga, Zn)O layer and in the (Ga, Zn)O region. In contrast, the movement frequency was likely to be low in the InO₂ layer (c-axis direction) because of the high activation barrier. This indicates that the proportion of hydrogen diffusing along the a-b plane is high in the layered structure including an InO₂ layer. In heat treatment at 450° C., however, hydrogen was found to diffuse in the InGaZnO₄ sufficiently

<2-(2). Site in which an Oxygen Vacancy V_{O} is Easily Formed>

The strength of bonding between a metal and oxygen differs depending on the kind or valence of the metal; therefore, the ease of formation of an oxygen vacancy V_{O} in InGaZnO₄ is probably determined by the kind, number, distance, or the like of metals bonded to oxygen. The ease of formation of an oxygen vacancy in an InGaZnO₄ crystal model was calculated.

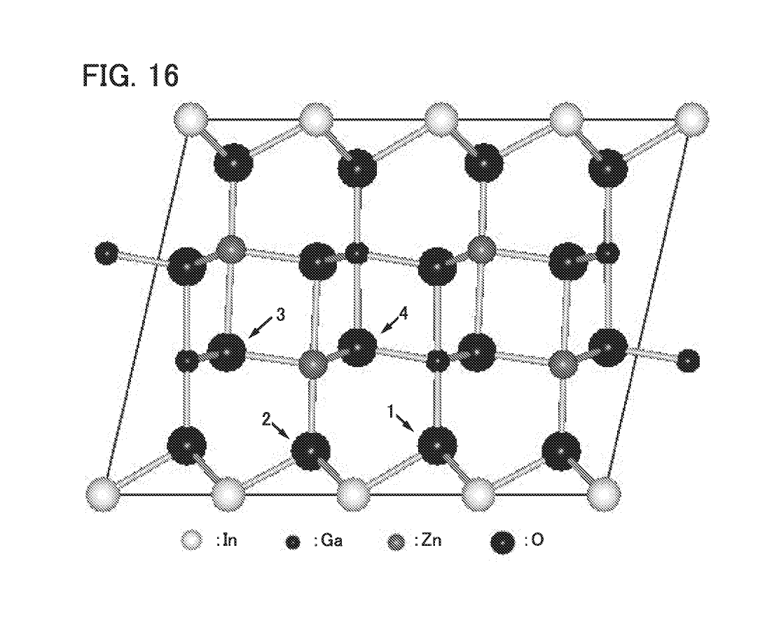

The model used for calculation is an InGaZnO₄ crystal model (112 atoms) shown in FIG. 16. In a (Ga, Zn)O region, Ga and Zn were placed so as to be energetically stable. In that case, there are four kinds of oxygen sites (1 to 4 in FIG. 16) depending on the kind and number of metals bonded to oxygen. Table 3 shows the four oxygen sites.

TABLE 3

| Oxygen site | | Bonding partner |
|---|---|---|
| InO₂ layer | 1 | In × 3, Ga × 1 |
| | 2 | In × 3, Zn × 1 |
| (Ga, Zn)O layer | 3 | Ga × 2, Zn × 2 |
| | 4 | Ga × 2, Zn × 2 |

An oxygen atom was extracted from each oxygen site in the above model, whereby oxygen vacancy models were obtained. Then, the total energy of each model after structure optimization was compared. Table 4 shows the calculation conditions.

TABLE 4

| Software | VASP |
|---|---|
| Functional | GGA/PBE |
| Pseudopotential | PAW |
| Cut-off energy | 500 eV |
| K points | 2 × 2 × 3 |

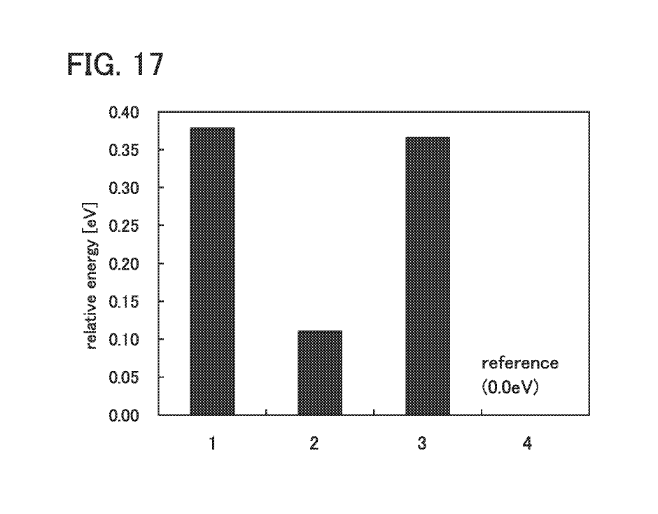

The total energy of each optimized structure was compared. FIG. 17 shows relative values of the total energies with the total energy of the oxygen vacancy model of the oxygen site 4 as a reference (0 eV). FIG. 17 indicates that an oxygen vacancy is most easily formed in the oxygen site 4, and relatively easily formed in the oxygen site 2. In contrast, an oxygen vacancy is less likely to be formed in the oxygen sites 1 and 3 than in the oxygen sites 2 and 4.

### <2-(3). Ease of Formation and Stability of H_{O}>

The calculation results described in <2-(1). Diffusion of H> showed that H diffused in InGaZnO₄ particularly when heat treatment was performed. Here, calculation was made on whether H easily enters an oxygen vacancy V_{O} if existing. A state in which H is in an oxygen vacancy V_{O} is referred to as H_{O} (also referred to as V_{O}H).

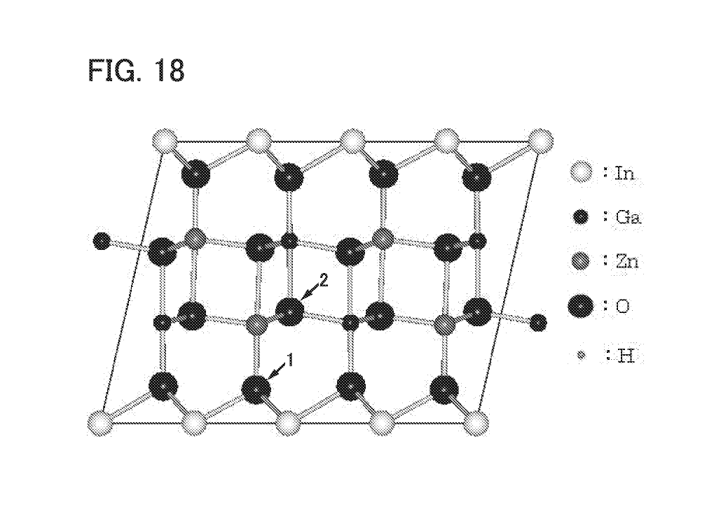

An InGaZnO₄ crystal model shown in FIG. 18 was used for calculation. The activation barrier (Eₐ) along the reaction path where H in H_{O} is released and bonded to oxygen was calculated by the NEB method. Table 5 shows the calculation results.

TABLE 5

| Software | VASP |
|---|---|
| Calculation | NEB method |
| Functional | GGA/PBE |
| Pseudopotential | PAW |
| Cut-off energy | 500 eV |
| K points | 2 × 2 × 3 |

The calculation results described in <2-(2). Site in which an oxygen vacancy V_{O} is easily formed> shows that there are two oxygen sites in which an oxygen vacancy V_{O} is easily formed. First, calculation was made on one of the oxygen sites in which an oxygen vacancy V_{O} is easily formed: an oxygen site (1 in FIG. 18) that was bonded to three In atoms and one Zn atom.

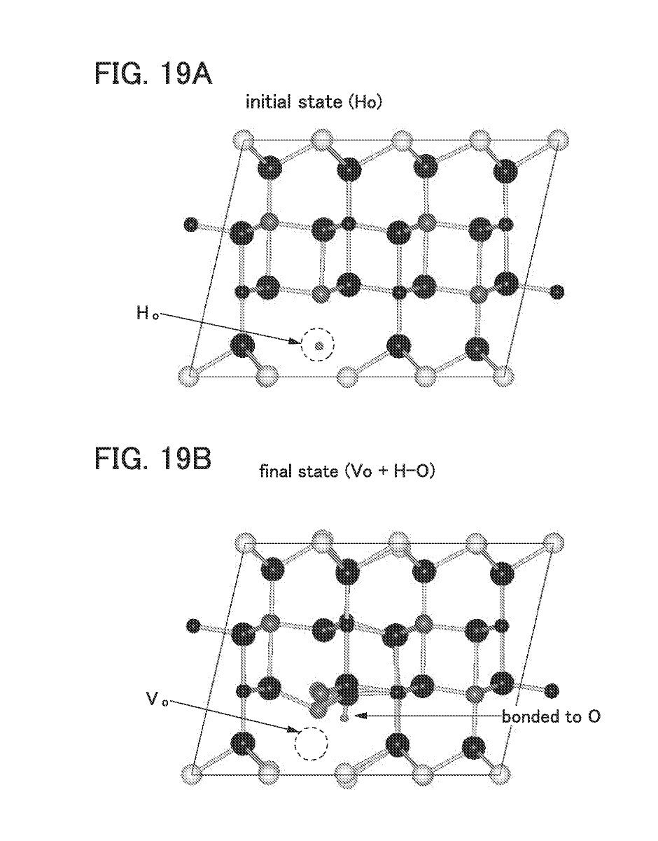

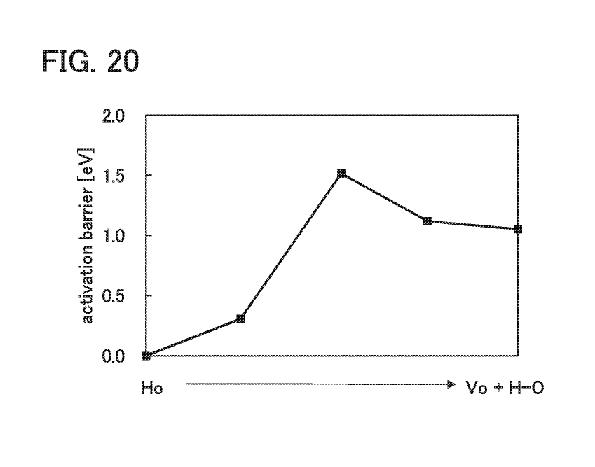

FIG. 19A shows a model in the initial state and FIG. 19B shows a model in the final state. FIG. 20 shows the calculated activation barrier (Eₐ) in the initial state and the final state. Note that here, the initial state refers to a state in which H exists in an oxygen vacancy V_{O} (H_{O}), and the final state refers to a structure including an oxygen vacancy V_{O} and a state in which H is bonded to oxygen bonded to one Ga atom and two Zn atoms (H—O).

From the calculation results, bonding of H in an oxygen vacancy V_{O} to another oxygen atom needs an energy of approximately 1.52 eV, while entry of H bonded to 0 in an oxygen vacancy V_{O} needs an energy of approximately 0.46 eV.

Reaction frequency (Γ) was calculated with use of the activation barriers (Eₐ) obtained by the calculation and the above Formula 2. In Formula 2, k_{B} represents the Boltzmann constant and T represents the absolute temperature.

The reaction frequency at 350° C. was calculated on the assumption that the frequency factor v is 10¹³ s⁻¹. The frequency of H transfer from the model shown in FIG. 19A to the model shown in FIG. 19B was found to be 5.52×10⁰ s⁻¹, whereas the frequency of H transfer from the model shown in FIG. 19B to the model shown in FIG. 19A was found to be 1.82×10⁹ s⁻¹. This suggests that H diffusing into InGaZnO₄ is likely to form H_{O} if an oxygen vacancy V_{O} exists in the neighborhood, and H is unlikely to be released once H_{O} is formed.

Next, on the basis of the calculation results described in <2-(2). Site in which an oxygen vacancy V_{O} is easily formed>, calculation was made on the other of the oxygen sites in which an oxygen vacancy V_{O} is easily formed: an oxygen site (2 in FIG. 18) that was bonded to one Ga atom and two Zn atoms.

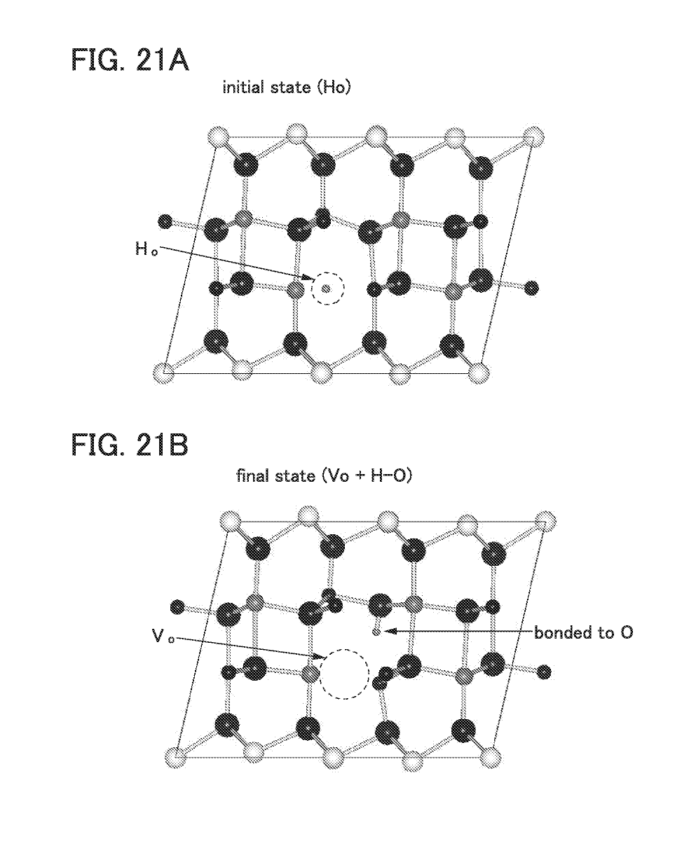

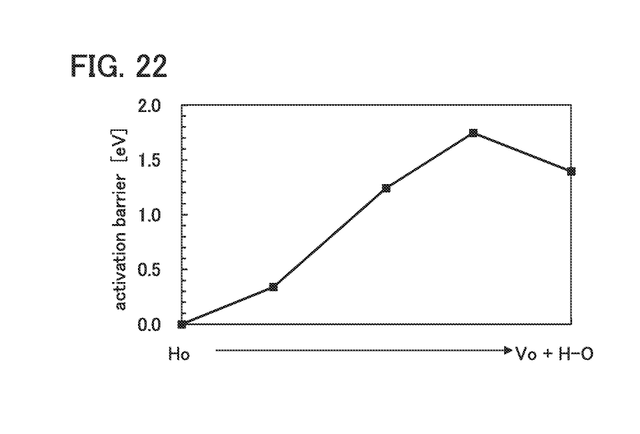

FIG. 21A shows a model in the initial state and FIG. 21B shows a model in the final state. FIG. 22 shows the calculated activation barrier (Eₐ) in the initial state and the final state. Note that here, the initial state refers to a state in which H exists in an oxygen vacancy V_{O} (H_{O}), and the final state refers to a structure including an oxygen vacancy V_{O} and a state in which H is bonded to oxygen bonded to one Ga atom and two Zn atoms (H—O).

From the calculation results, bonding of H in an oxygen vacancy V_{O} to another O needs an energy of approximately 1.75 eV, while entry of H bonded to O in an oxygen vacancy V_{O} needs an energy of approximately 0.35 eV.

Reaction frequency (Γ) was calculated with use of the activation barriers (Eₐ) obtained by the calculation and Formula 2.

The reaction frequency at 350° C. was calculated on the assumption that the frequency factor v=10¹³ s⁻¹. The frequency of H transfer from the model shown in FIG. 21A to the model shown in FIG. 21B was 7.53×10⁻² s⁻¹, whereas the frequency of H transfer from the model shown in FIG. 21B to the model shown in FIG. 21A was 1.44×10¹⁰ s⁻¹. This suggests that H is unlikely to be released once H_{O} is formed.

From the above results, it was found that H in InGaZnO₄ easily diffused in heat treatment and if an oxygen vacancy V_{O} existed, H was likely to enter the oxygen vacancy V_{O} to be H_{O}.

### <2-(4). Transition Level of H_{O}>

The calculation by the NEB method, which was described in <2-(3). Ease of formation and stability of H_{O}>, indicates that in the case where an oxygen vacancy V_{O} and H exist in InGaZnO₄, the oxygen vacancy V_{O} and H easily form H_{O} and H_{O} is stable. To determine whether H_{O} is related to a carrier trap, the transition level of H_{O} was calculated.

The model used for calculation is the InGaZnO₄ crystal model (112 atoms) shown in FIG. 18. The oxygen site in which an oxygen vacancy V_{O} is easily formed is the oxygen site 1 in FIG. 18, which is bonded to three In atoms and one Zn atom, or the oxygen site 2 in FIG. 18, which is bonded to one Ga atom and two Zn atoms. Thus, Ho models of the oxygen sites 1 and 2 were made to calculate the transition levels. Table 6 shows the calculation conditions.

TABLE 6

| Software | VASP |
|---|---|
| Model | InGaZnO₄ crystal (112 atoms) |
| Functional | HSE06 |
| Fraction of exact exchange | 0.25 |
| Pseudopotential | GGA-PBE |
| Cut-off energy | 800 eV |
| K points | 1 × 1 × 1 |

The fraction of the exact exchange was adjusted to have a band gap close to the experimental value. As a result, the band gap of the InGaZnO₄ crystal model without defects was 3.08 eV that is close to the experimental value, 3.15 eV.

The transition level (ε(q/q′)) of a model having defect D can be calculated by the following Formula 3. Note that ΔE(D^{q}) represents the formation energy of defect D at charge q, which is calculated by Formula 4.

$$\begin{matrix}ɛ ( q / {q}^{′} ) = \frac{Δ E ( {D}^{q} ) - Δ E ( {D}^{{q}^{′}} )}{{q}^{′} - q} & [ Formula 3 ] \\ Δ E ( {D}^{q} ) = {E}_{tot} ( {D}^{q} ) - {E}_{tot} ( bulk ) + {\sum }_{i} Δ {n}_{i} {μ}_{i} + q ( {ɛ}_{V B M} + Δ {V}_{q} + {E}_{F} ) & [ Formula 4 ]\end{matrix}$$

In Formulae 3 and 4, Eₜₒₜ(D^{q}) represents the total energy of the model having defect D at the charge q in, Eₜₒₜ(bulk) represents the total energy in a model without defects (complete crystal), Δnᵢ represents a change in the number of atoms i contributing to defects, μᵢ represents the chemical potential of atom i, ε_{VBM} represents the energy of the valence band maximum in the model without defects, ΔV_{q} represents the correction term relating to the electrostatic potential, and E_{F} represents the Fermi energy.

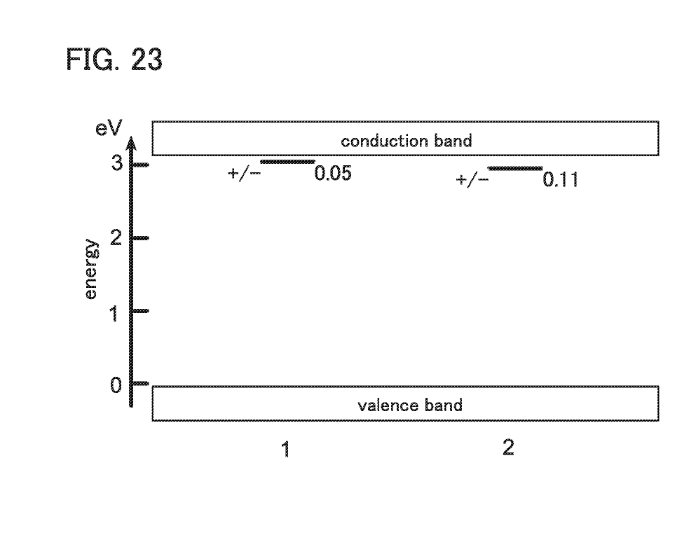

FIG. 23 shows the transition levels of H_{O} obtained from the above formulae. The numbers in FIG. 23 represent the depth from the conduction band minimum. In FIG. 23, the transition level of H_{O} in the oxygen site 1 is at 0.05 eV from the conduction band minimum, and the transition level of H_{O} in the oxygen site 2 is at 0.11 eV from the conduction band minimum. Therefore, these H_{O} would be related to electron traps, that is, H_{O} was found to behave as a donor. It was also found that InGaZnO₄ including H_{O} had conductivity.

<2-(5). Release of H₂O from Top Surface>

Next, calculation was made on the steps in which H in InGaZnO₄ is released from the top surface of InGaZnO₄ as H₂O.

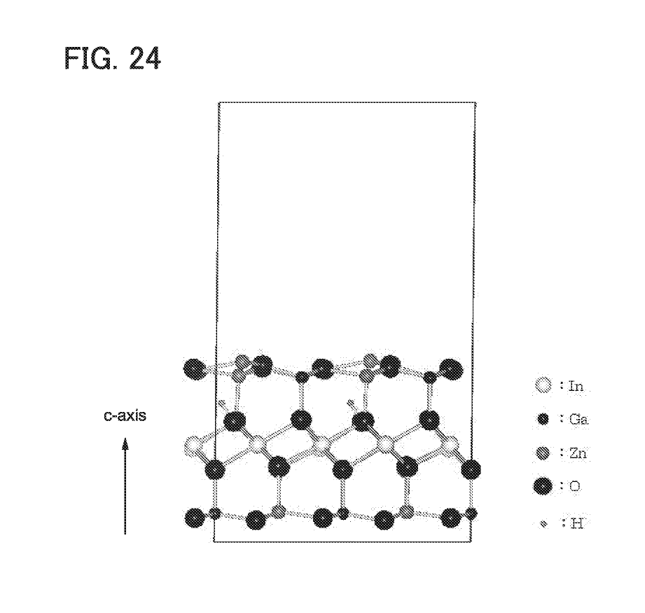

A cleavage surface of an InGaZnO₄ crystal model was assumed to be the top surface. In other words, the model used was an InGaZnO₄ crystal (112 atoms) whose outermost surface was the (Ga, Zn)O plane. FIG. 24 shows the calculation model and Table 7 shows the calculation conditions.

TABLE 7

| Software | VASP |
|---|---|
| Functional | GGA/PBE |
| Pseudopotential | PAW |
| Cut-off energy | 500 eV |
| K points | 2 × 2 × 1 |

The H₂O release steps were calculated as follows on the assumption that the initial structure of the reaction path was an InGaZnO₄ top surface model in which two hydrogen atoms were bonded to 0 in an InO₂ layer.

Steps (1) to (2): A first H atom is bonded to the inner side of an O atom on the top surface.
Steps (2) to (3): The first H atom moves outside the O atom on the top surface.
Steps (3) to (4): A second H approaches.
Steps (4) to (5): The second H is bonded to the inner side of OH on the top surface.
Steps (5) to (6): The second H moves outside the O atom on the top surface.
Steps (6) to (7): H₂O is released.

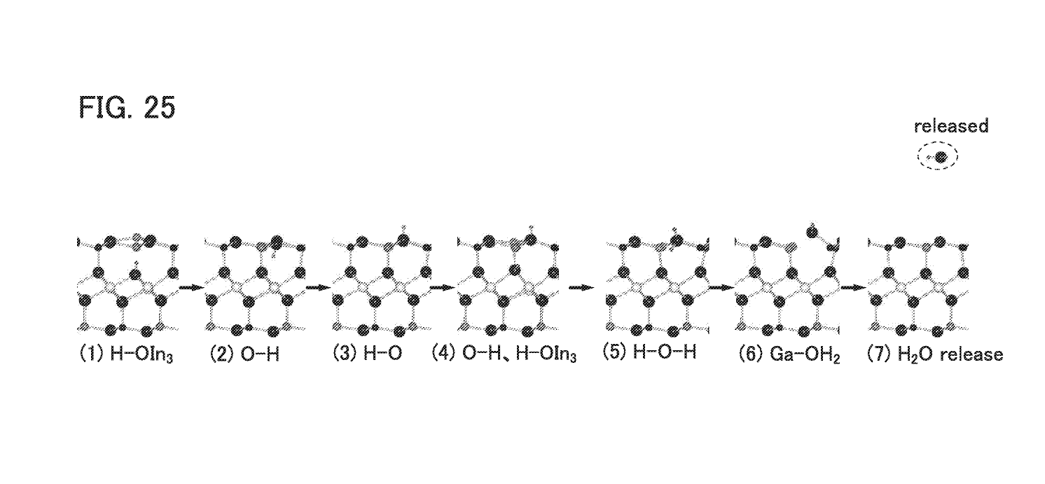

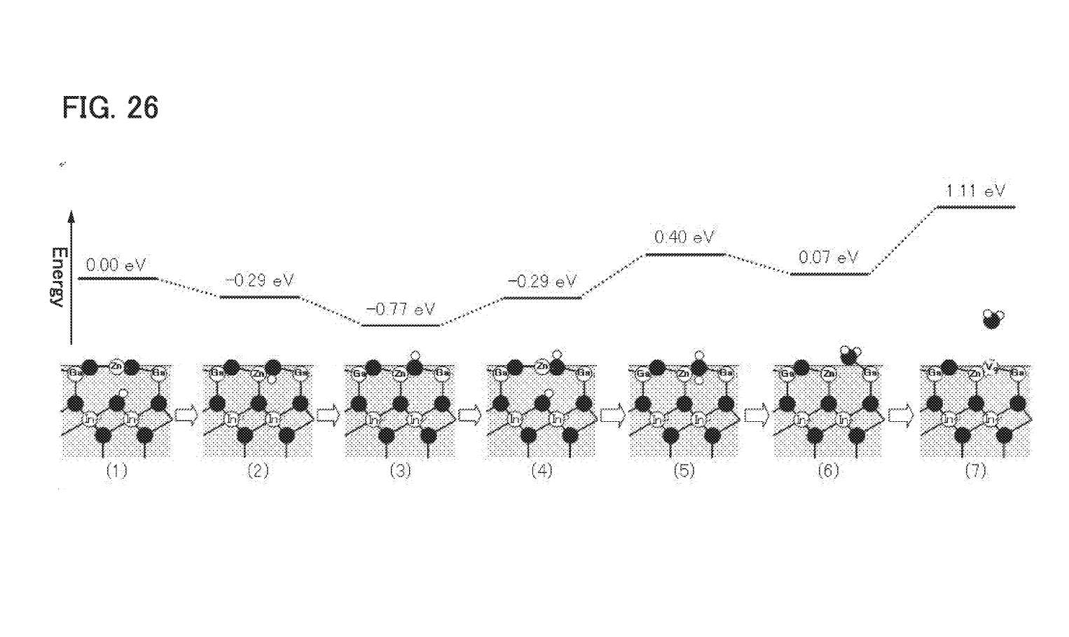

FIG. 25 shows the structures of the model in the reaction paths of the above steps. FIG. 26 shows energy changes with the energy of the initial structure as a reference (0.00 eV). Note that the upper side of FIG. 26 shows the energy changes in the steps of (1) to (7) in FIG. 25, and the lower side of FIG. 26 shows schematic diagrams of reaction of O and H atoms in InGaZnO₄ and on the top surface of InGaZnO₄ in the steps of (1) to (7).

The calculation results showed that the highest energy, 1.04 eV, was obtained in the reaction path (steps of (6) to (7)) in which H₂O is released from the state where two H atoms are bonded to an O atom on the top surface and an oxygen vacancy V_{O} is formed. Thus, the reaction frequency (Γ) of the steps of (6) to (7) was calculated by Formula 2.

The reaction frequency at 350° C. was calculated on the assumption that the frequency factor v=1×10¹³ s⁻¹, then, a reaction frequency Γ of 3.66×10⁴ s⁻¹ was obtained. This suggests that H could be released as H₂O to form an oxygen vacancy V_{O} in an actual process.

<2-(6). Release of H₂O from Side Surface>

Next, calculation was made on the steps in which H in InGaZnO₄ is released from the side surface of InGaZnO₄ as H₂O.

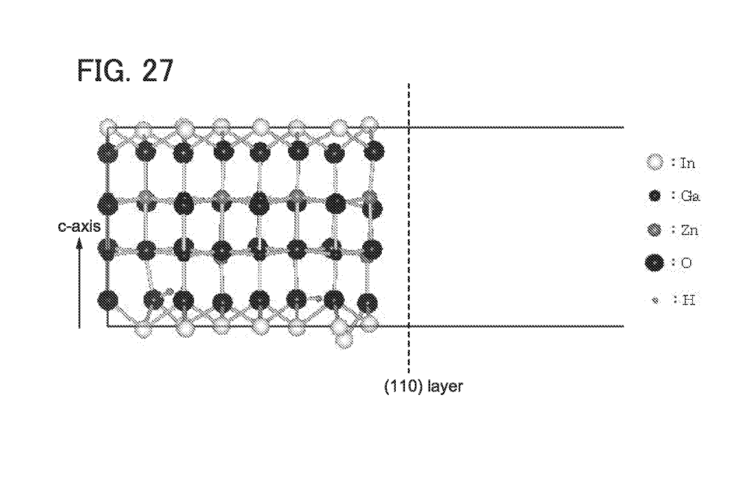

As an InGaZnO₄ crystal model, a model assuming a (110) plane as a side surface (the number of atoms: 112) was used. FIG. 27 shows the calculation model and Table 8 shows the calculation conditions.

TABLE 8

| Software | VASP |
|---|---|
| Functional | GGA/PBE |
| Pseudopotential | PAW |
| Cut-off energy | 500 eV |
| K points | 1 × 2 × 3 |

The H₂O release steps were calculated as follows on the assumption that the initial structure of the reaction path was an InGaZnO₄ side surface model in which two hydrogen atoms were bonded to an O atom in an InO₂ layer.

Steps (1) to (2): A first H atom is bonded to the inner side of an O atom on the side surface.
Steps (2) to (3): The first H atom moves outside the O atom on the side surface.
Steps (3) to (4): A second H approaches.
Steps (4) to (5): The second H moves outside the O atom on the side surface.
Steps (5) to (6): H₂O is released.

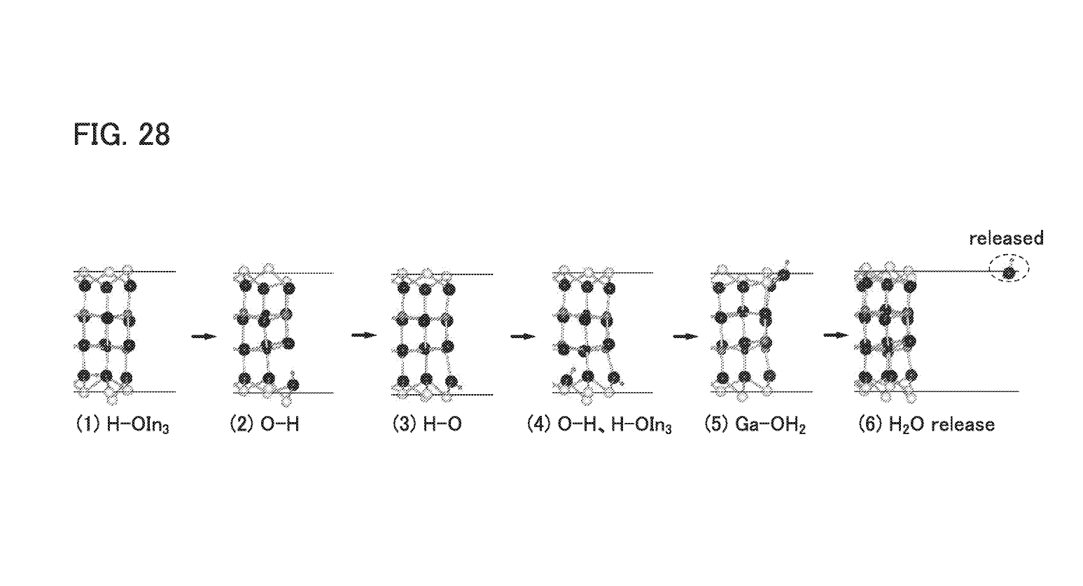

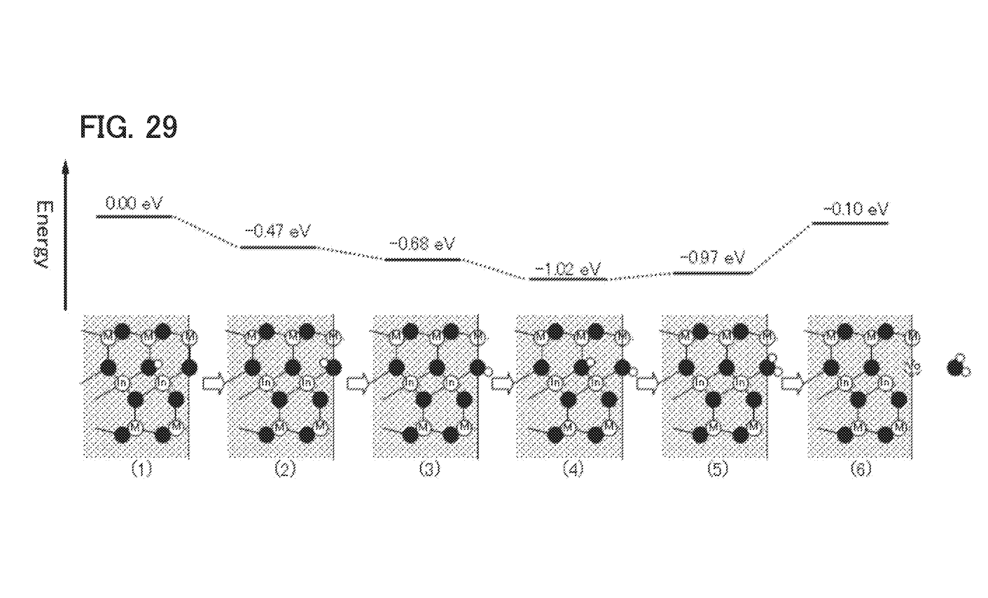

FIG. 28 shows the structures of the model in the reaction paths of the above steps. FIG. 29 shows energy changes with the energy of the initial structure as a reference (0.00 eV). Note that the upper side of FIG. 29 shows the energy changes in the steps of (1) to (6) in FIG. 29, and the lower side of FIG. 29 shows schematic diagrams of reaction of O and H atoms in InGaZnO₄ and on the side surface of InGaZnO₄ in the steps of (1) to (6).

The calculation results showed that the highest energy, 0.87 eV, was obtained in the reaction path (steps of (5) to (6)) in which H₂O is released from the state where two H atoms are bonded to an O atom on the side surface and an oxygen vacancy V_{O} is formed. Thus, the reaction frequency (Γ) of the steps of (5) to (6) was calculated by Formula 2.

The reaction frequency at 350° C. was calculated on the assumption that the frequency factor v=1×10¹³ s⁻¹, then, a reaction frequency Γ of 9.13×10⁵ s⁻¹ was obtained. This suggests that H could be released as H₂O to form an oxygen vacancy V_{O} in an actual process.

### Embodiment 4

In this embodiment, a structural example of a semiconductor device including the transistor of one embodiment of the present invention will be described with reference to drawings.

### [Cross-Sectional Structure]

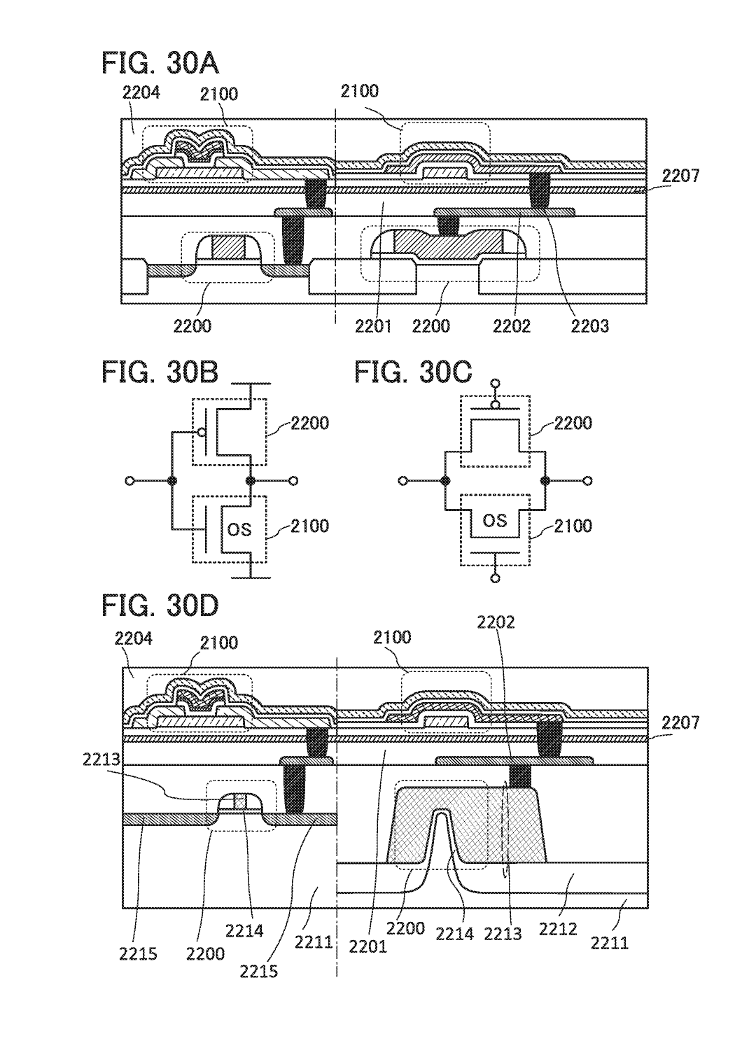

FIG. 30A is a cross-sectional view of a semiconductor device of one embodiment of the present invention. The semiconductor device illustrated in FIG. 30A includes a transistor 2200 containing a first semiconductor material in a lower portion and a transistor 2100 containing a second semiconductor material in an upper portion. A cross-sectional view of the transistors in a channel length direction is on the left side of a dashed-dotted line, and a cross-sectional view of the transistors in a channel width direction is on the right side of the dashed-dotted line.

Note that the transistor 2100 may be provided with a back gate.

The first and second semiconductor materials preferably have different energy gaps. For example, the first semiconductor material can be a semiconductor material other than an oxide semiconductor (examples of such a semiconductor material include silicon (including strained silicon), germanium, silicon germanium, silicon carbide, gallium arsenide, aluminum gallium arsenide, indium phosphide, gallium nitride, and an organic semiconductor), and the second semiconductor material can be an oxide semiconductor. A transistor using a material other than an oxide semiconductor, such as single crystal silicon, can operate at high speed easily. On the other hand, a transistor including an oxide semiconductor has a low off-state current.

The transistor 2200 may be either an n-channel transistor or a p-channel transistor, and an appropriate transistor may be used in accordance with a circuit. Furthermore, the specific structure of the semiconductor device, such as the material or the structure used for the semiconductor device, is not necessarily limited to those described here except for the use of the transistor of one embodiment of the present invention which uses an oxide semiconductor.

FIG. 30A illustrates a structure in which the transistor 2100 is provided over the transistor 2200 with an insulating film 2201 and an insulating film 2207 provided therebetween. A plurality of wirings 2202 are provided between the transistor 2200 and the transistor 2100. Furthermore, wirings and electrodes provided over and under the insulating films are electrically connected to each other through a plurality of plugs 2203 embedded in the insulating films. An interlayer insulating film 2204 covering the transistor 2100 is provided.

The stack of the two kinds of transistors reduces the area occupied by the circuit, allowing a plurality of circuits to be highly integrated.

Here, in the case where a silicon-based semiconductor material is used for the transistor 2200 provided in a lower portion, hydrogen in an insulating film provided in the vicinity of the semiconductor film of the transistor 2200 terminates dangling bonds of silicon; accordingly, the reliability of the transistor 2200 can be improved. Meanwhile, in the case where an oxide semiconductor is used for the transistor 2100 provided in an upper portion, hydrogen in an insulating film provided in the vicinity of the semiconductor film of the transistor 2100 becomes a factor of generating carriers in the oxide semiconductor; thus, the reliability of the transistor 2100 might be decreased. Therefore, in the case where the transistor 2100 using an oxide semiconductor is provided over the transistor 2200 using a silicon-based semiconductor material, it is particularly effective that the insulating film 2207 having a function of preventing diffusion of hydrogen is provided between the transistors 2100 and 2200. The insulating film 2207 makes hydrogen remain in the lower portion, thereby improving the reliability of the transistor 2200. In addition, since the insulating film 2207 suppresses diffusion of hydrogen from the lower portion to the upper portion, the reliability of the transistor 2100 also can be improved.

The insulating film 2207 can be, for example, formed using aluminum oxide, aluminum oxynitride, gallium oxide, gallium oxynitride, yttrium oxide, yttrium oxynitride, hafnium oxide, hafnium oxynitride, or yttria-stabilized zirconia (YSZ).

Furthermore, a blocking film having a function of preventing entry of hydrogen may be formed over the transistor 2100 to cover the transistor 2100 including an oxide semiconductor film. For the blocking film, a material that is similar to that of the insulating film 2207 can be used, and in particular, aluminum oxide is preferably used. The aluminum oxide film has a high shielding (blocking) effect of preventing penetration of both oxygen and impurities such as hydrogen and moisture. Thus, by using the aluminum oxide film as the blocking film covering the transistor 2100, release of oxygen from the oxide semiconductor film included in the transistor 2100 and entry of water and hydrogen into the oxide semiconductor film can be prevented.

Note that the transistor 2200 can be a transistor of various types without being limited to a planar type transistor. For example, the transistor 2200 can be a FIN-type transistor, a TRI-GATE transistor, or the like. An example of a cross-sectional view in such a case is shown in FIG. 30D. An insulating film 2212 is provided over a semiconductor substrate 2211. The semiconductor substrate 2211 has a projecting portion with a thin tip (also referred to a fin). Note that an insulating film may be provided over the protruding portion. The insulating film functions as a mask for preventing the semiconductor substrate 2211 from being etched when the protruding portion is formed. Alternatively, the protruding portion may not have the thin tip; a protruding portion with a cuboid-like protruding portion and a protruding portion with a thick tip are permitted, for example. A gate insulating film 2214 is provided over the protruding portion of the semiconductor substrate 2211, and a gate electrode 2213 is provided over the gate insulating film 2214. Although the gate electrode 2213 has a single-layer structure in this embodiment, one embodiment of the present invention is not limited to this example, and the gate electrode 2213 may have a stacked-layer structure of two or more layers. Source and drain regions 2215 are formed in the semiconductor substrate 2211. Note that here is shown an example in which the semiconductor substrate 2211 includes the projection portion; however, a semiconductor device of one embodiment of the present invention is not limited thereto. For example, a semiconductor region having a protruding portion may be formed by processing an SOI substrate.

### Circuit Configuration Example

In the above structure, electrodes of the transistor 2100 and the transistor 2200 can be connected in a variety of ways; thus, a variety of circuits can be formed. Examples of circuit configurations which can be achieved by using a semiconductor device of one embodiment of the present invention are shown below.

A circuit diagram in FIG. 30B shows a configuration of what is called a CMOS circuit in which the p-channel transistor 2200 and the n-channel transistor 2100 are connected to each other in series and in which gates of them are connected to each other.

A circuit diagram in FIG. 30C shows a configuration in which sources of the transistors 2100 and 2200 are connected to each other and drains of the transistors 2100 and 2200 are connected to each other. With such a configuration, the transistors can function as a so-called analog switch.

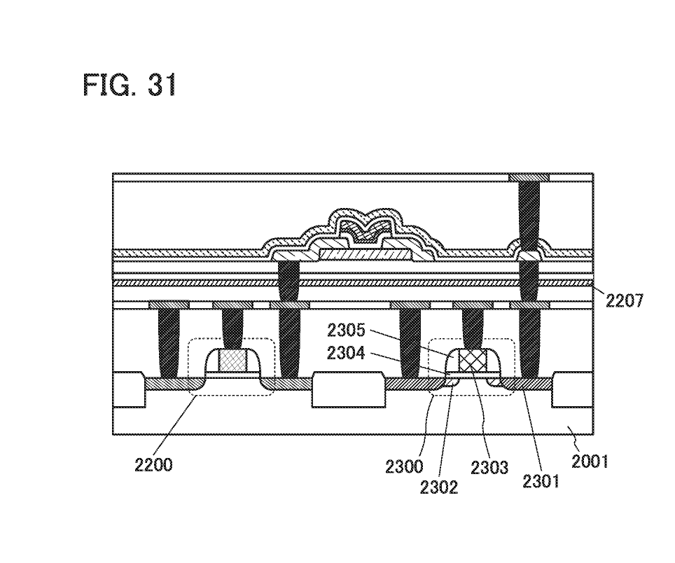

FIG. 31 is a cross-sectional view of a semiconductor device in which a CMOS circuit includes a transistor 2200 and a transistor 2300 each having a channel formed using a first semiconductor material.

The transistor 2300 includes impurity regions 2301 serving as a source region or a drain region, a gate electrode 2303, a gate insulating film 2304, and a sidewall insulating film 2305. The transistor 2300 may also include an impurity region 2302 serving as an LDD region under the sidewall insulating film 2305. The description for FIG. 30A can be referred to for the other components in FIG. 31.

The transistors 2200 and 2300 preferably have opposite polarities. For example, when the transistor 2200 is a p-channel transistor, the transistor 2300 is preferably an n-channel transistor.

A photoelectric conversion element such as a photodiode may be provided in the semiconductor devices illustrated in FIG. 30A and FIG. 31.

The photodiode can be formed using a single crystal semiconductor or a polycrystalline semiconductor. The photodiode formed using a single crystal semiconductor or a polycrystalline semiconductor is preferable because of its high light detection sensitivity.

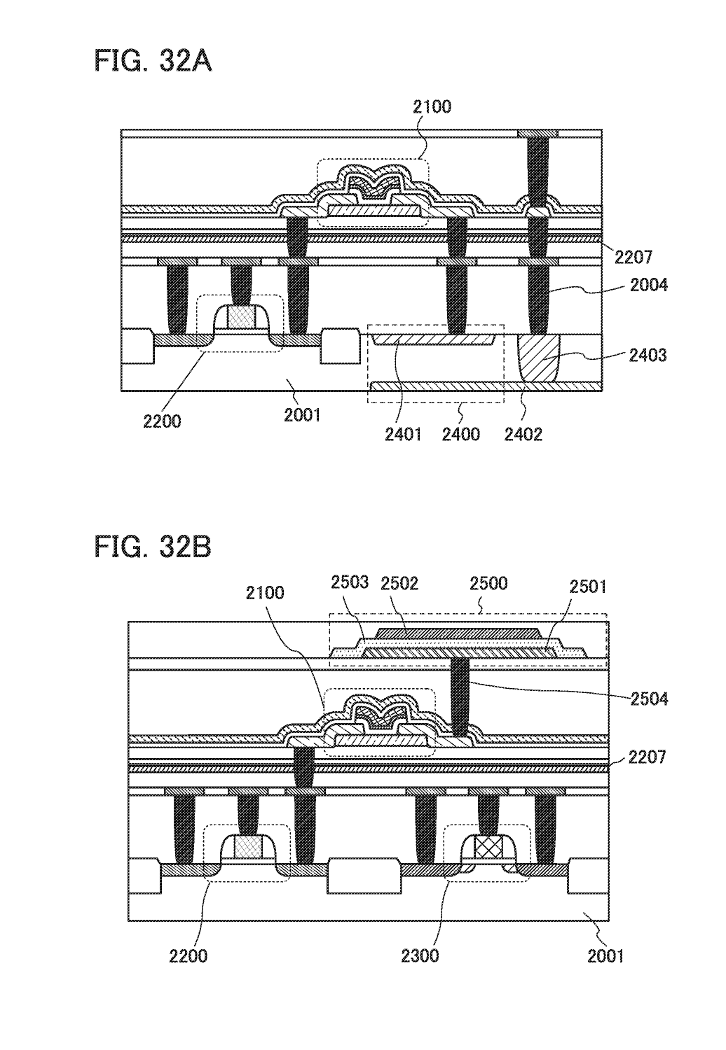

FIG. 32A is a cross-sectional view of a semiconductor device where a substrate 2001 is provided with a photodiode 2400. The photodiode 2400 includes a conductive film 2401 having a function as one of an anode and a cathode, a conductive film 2402 having a function as the other of the anode and the cathode, and a conductive film 2403 electrically connecting the conductive film 2402 and a plug 2004. The conductive films 2401 to 2403 may be formed by injecting an impurity in the substrate 2001.

Although the photodiode 2400 is provided so that a current flows in the vertical direction with respect to the substrate 2001 in FIG. 32A, the photodiode 2400 may be provided so that a current flows in the lateral direction with respect to the substrate 2001.

FIG. 32B is a cross-sectional view of a semiconductor device in which a photodiode 2500 is provided over the transistor 2100. The photodiode 2500 includes a conductive film 2501 having a function as one of an anode and a cathode, a conductive film 2502 having a function as the other of the anode and the cathode, and a semiconductor 2503. Furthermore, the photodiode 2500 is electrically connected to the transistor 2100 through a plug 2504.

In FIG. 32B, the photodiode 2500 may be provided at the same level as the transistor 2100. Alternatively, the photodiode 2500 may be provided at the level between the transistor 2200 and the transistor 2100.

The description for FIG. 30A and FIG. 31 can be referred to for the details of other components in FIGS. 32A and 32B.

The photodiode 2400 or the photodiode 2500 may be formed using a material capable of generating charge by absorbing a radiation. Examples of a material capable of generating electrical charges by absorbing radiation include selenium, lead iodide, mercury iodide, gallium arsenide, CdTe, and CdZn.

The use of selenium for the photodiode 2400 or the photodiode 2500 can provide a photoelectric conversion element having a light absorption coefficient in a wide wavelength range of visible light, ultraviolet light, X-rays, and gamma rays, for example.

### <Memory Device>

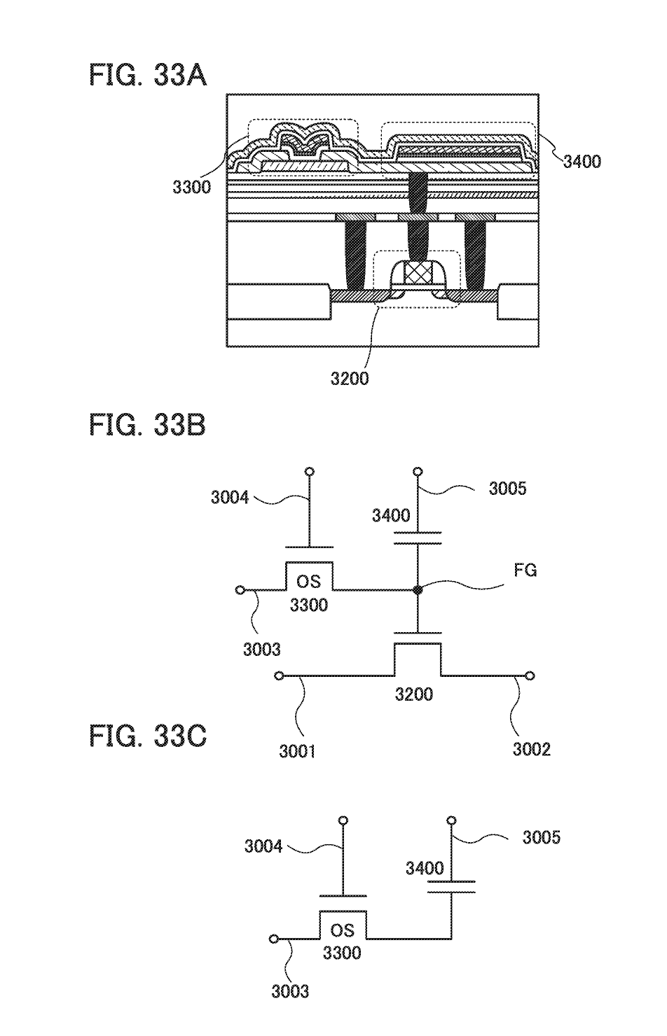

Examples of a semiconductor device (memory device) which includes the transistor of one embodiment of the present invention, which can retain stored data even when not powered, and which has an unlimited number of write cycles are shown in FIGS. 33A to 33C. Note that FIG. 33B is a circuit diagram of the structure in FIG. 33A.

The semiconductor device illustrated in FIGS. 33A and 33B includes a transistor 3200 including a first semiconductor material, a transistor 3300 including a second semiconductor material, and a capacitor 3400. As the transistor 3300, the transistor described in Embodiment 1 can be used.

The transistor 3300 is a transistor in which a channel is formed in a semiconductor including an oxide semiconductor. Since the off-state current of the transistor 3300 is small, stored data can be retained for a long period. In other words, power consumption can be sufficiently reduced because a semiconductor memory device in which refresh operation is unnecessary or the frequency of refresh operation is extremely low can be provided.

In FIG. 33B, a first wiring 3001 is electrically connected to a source of the transistor 3200. A second wiring 3002 is electrically connected to a drain of the transistor 3200. A third wiring 3003 is electrically connected to one of a source and a drain of the transistor 3300. A fourth wiring 3004 is electrically connected to the gate of the transistor 3300. A gate of the transistor 3200 and the other of the source and the drain of the transistor 3300 are electrically connected to one electrode of the capacitor 3400. A fifth wiring 3005 is electrically connected to the other electrode of the capacitor 3400.

The semiconductor device in FIG. 33A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to the gate of the transistor 3200 and the capacitor 3400. That is, predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge supplied to the gate of the transistor 3200 is retained (retaining).

Since the off-state current of the transistor 3300 is extremely small, the charge of the gate of the transistor 3200 is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the gate of the transistor 3200. This is because in the case of using an n-channel transistor as the transistor 3200, an apparent threshold voltage Vₜₕ_{_}_{H} at the time when the high-level charge is given to the gate of the transistor 3200 is lower than an apparent threshold voltage Vₜₕ_{_}_{L} at the time when the low-level charge is given to the gate of the transistor 3200. Here, an apparent threshold voltage refers to the potential of the fifth wiring 3005 that is needed to turn on the transistor 3200. Thus, the potential of the fifth wiring 3005 is set to a potential V_{O} that is between Vₜₕ_{_}_{H} and Vₜₕ_{_}_{L}, whereby charge supplied to the gate of the transistor 3200 can be determined. For example, in the case where the high-level charge is supplied to the gate electrode of the transistor 3200 in writing and the potential of the fifth wiring 3005 is V_{O} (>Vₜₕ_{_}_{H}), the transistor 3200 is turned on. In the case where the low-level charge is supplied to the gate electrode of the transistor 3200 in writing, even when the potential of the fifth wiring 3005 is V_{O} (<Vₜₕ_{_}_{L}), the transistor 3200 remains off. Thus, the data retained in the gate electrode of the transistor 3200 can be read by determining the potential of the second wiring 3002.

Note that in the case where memory cells are arrayed, only data of desired memory cells need to be read. The fifth wiring 3005 in the case where data is not read may be supplied with a potential at which the transistor 3200 is turned off regardless of the state of the gate, that is, a potential lower than Vₜₕ_{_}_{H}. Alternatively, the fifth wiring 3005 may be supplied with a potential at which the transistor 3200 is turned on regardless of the state of the gate, that is, a potential higher than Vₜₕ_{_}_{L}.

The semiconductor device illustrated in FIG. 33C is different from the semiconductor device illustrated in FIG. 33A in that the transistor 3200 is not provided. Also in this case, writing and holding of data can be performed in a manner similar to the above.

Next, reading of data in the semiconductor device illustrated in FIG. 33C is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies depending on the potential of the first terminal of the capacitor 3400 (or the charge accumulated in the capacitor 3400).

For example, the potential of the third wiring 3003 after the charge redistribution is (C_{B}×V_{BO} C×V)/(C_{B}+C), where V is the potential of the first terminal of the capacitor 3400, C is the capacitance of the capacitor 3400, C_{B} is the capacitance component of the third wiring 3003, and V_{BO} is the potential of the third wiring 3003 before the charge redistribution. Thus, it can be found that, assuming that the memory cell is in either of two states in which the potential of the first terminal of the capacitor 3400 is V₁ and V₀ (V₁>V₀), the potential of the third wiring 3003 in the case of retaining the potential V₁ (=(C_{B}×V_{BO} C×V₁)/(C_{B}+C)) is higher than the potential of the third wiring 3003 in the case of retaining the potential V₀ (=(C_{B}×V_{BO}+C×V₀)/(C_{B}+C).

Then, by comparing the potential of the third wiring 3003 with a predetermined potential, data can be read.

In this case, a transistor including the first semiconductor material may be used for a driver circuit for driving a memory cell, and a transistor including the second semiconductor material may be stacked over the driver circuit as the transistor 3300.

When including a transistor that has a channel formation region including an oxide semiconductor and has an extremely small off-state current, the semiconductor device described in this embodiment can retain stored data for an extremely long period. In other words, refresh operation becomes unnecessary or the frequency of the refresh operation can be extremely low, which leads to a sufficient reduction in power consumption. Moreover, stored data can be retained for a long time even when power is not supplied (note that a potential is preferably fixed).

Furthermore, in the semiconductor device described in this embodiment, high voltage is not needed for writing data and there is no problem of deterioration of elements. Unlike in a conventional nonvolatile memory, for example, it is not necessary to inject and extract electrons into and from a floating gate; thus, a problem such as deterioration of a gate insulating layer is not caused. That is, the semiconductor device of the disclosed invention does not have a limit on the number of times of data rewriting, which is a problem of a conventional nonvolatile memory, and the reliability thereof is drastically improved. Furthermore, data is written depending on the state of the transistor (on or off), whereby high-speed operation can be easily achieved.

The memory device described in this embodiment can also be used in an LSI, such as a central processing unit (CPU), a digital signal processor (DSP), a custom LSI, or a programmable logic device (PLD) and a radio frequency identification (RFID) tag, for example.

The structures, the methods, and the like described in this embodiment can be combined as appropriate with any of the structures, the methods, and the like described in the other embodiments.

### Embodiment 5

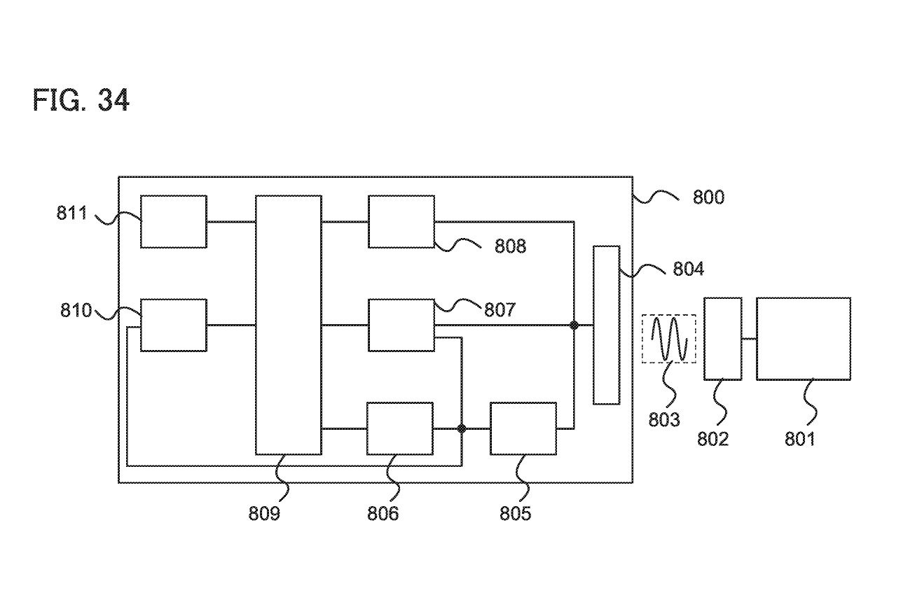

In this embodiment, an RF device tag that includes any of the transistors and the memory devices described in the above embodiments will be described with reference to FIG. 34.

The RF device tag of this embodiment includes a memory circuit, stores necessary data in the memory circuit, and transmits and receives data to/from the outside by using contactless means, for example, wireless communication. With these features, the RF device tag can be used for an individual authentication system in which an object or the like is recognized by reading the individual information, for example. Note that the RF device tag is required to have extremely high reliability in order to be used for this purpose.

A configuration of the RF device tag is described with reference to FIG. 34. FIG. 34 is a block diagram illustrating a configuration example of an RF device tag.

As shown in FIG. 34, an RF device tag 800 includes an antenna 804 that receives a radio signal 803 that is transmitted from an antenna 802 connected to a communication device 801 (also referred to as an interrogator, a reader/writer, or the like). The RF device tag 800 includes a rectifier circuit 805, a constant voltage circuit 806, a demodulation circuit 807, a modulation circuit 808, a logic circuit 809, a memory circuit 810, and a ROM 811. A transistor having a rectifying function included in the demodulation circuit 807 may be formed using a material that enables a reverse current to be low enough, for example, an oxide semiconductor. This can suppress the phenomenon of a rectifying function becoming weaker due to generation of a reverse current and prevent saturation of the output from the demodulation circuit. In other words, the input to the demodulation circuit and the output from the demodulation circuit can have a relation closer to a linear relation. Note that data transmission methods are roughly classified into the following three methods: an electromagnetic coupling method in which a pair of coils is provided so as to face each other and communicates with each other by mutual induction, an electromagnetic induction method in which communication is performed using an induction field, and a radio wave method in which communication is performed using a radio wave. Any of these methods can be used in the RF device tag 800 described in this embodiment.

Next, a configuration of each circuit is described. The antenna 804 exchanges the radio signal 803 with the antenna 802 that is connected to the communication device 801. The rectifier circuit 805 generates an input potential by rectification, for example, half-wave voltage doubler rectification of an input alternating signal generated by reception of a radio signal at the antenna 804 and smoothing of the rectified signal with a capacitor provided in a later stage in the rectifier circuit 805. Note that a limiter circuit may be provided on an input side or an output side of the rectifier circuit 805. The limiter circuit controls electric power so that electric power that is higher than or equal to certain electric power is not input to a circuit in a later stage if the amplitude of the input alternating signal is high and an internal generation voltage is high.

The constant voltage circuit 806 generates a stable power supply voltage from an input potential and supplies it to each circuit. Note that the constant voltage circuit 806 may include a reset signal generation circuit. The reset signal generation circuit is a circuit that generates a reset signal of the logic circuit 809 by utilizing rise of the stable power supply voltage.

The demodulation circuit 807 demodulates the input alternating signal by envelope detection and generates the demodulated signal. The modulation circuit 808 performs modulation in accordance with data to be output from the antenna 804.

The logic circuit 809 analyzes and processes the demodulated signal. The memory circuit 810 holds the input data and includes a row decoder, a column decoder, a memory region, and the like. The ROM 811 stores an identification number (ID) or the like and outputs it in accordance with processing.

Note that the decision whether each circuit described above is provided or not can be made as appropriate as needed.

Here, the memory circuit described in the above embodiment can be used as the memory circuit 810. Since the memory circuit of one embodiment of the present invention can retain data even when not powered, the memory circuit can be favorably used for an RF device tag. In addition, the memory circuit of one embodiment of the present invention needs much lower power (voltage) for data writing than a conventional nonvolatile memory; thus, it is possible to prevent a difference between the maximum communication range in data reading and that in data writing. Furthermore, it is possible to suppress malfunction or incorrect writing that is caused by power shortage in data writing.

Since the memory circuit of one embodiment of the present invention can be used as a nonvolatile memory, it can also be used as the ROM 811. In this case, it is preferable that a manufacturer separately prepare a command for writing data to the ROM 811 so that a user cannot rewrite data freely. Since the manufacturer gives identification numbers before shipment of products, identification numbers can be put only to good products to be shipped without putting them to all the manufactured RF device tags. Thus, the identification numbers of the shipped products are in series and customer management corresponding to the shipped products is easily performed.

At least part of this embodiment can be implemented in combination with any of the other embodiments described in this specification as appropriate.

### Embodiment 6

In this embodiment, a CPU in which at least the transistor described in any of the above embodiments can be used and the memory device described in the above embodiment is included is described.

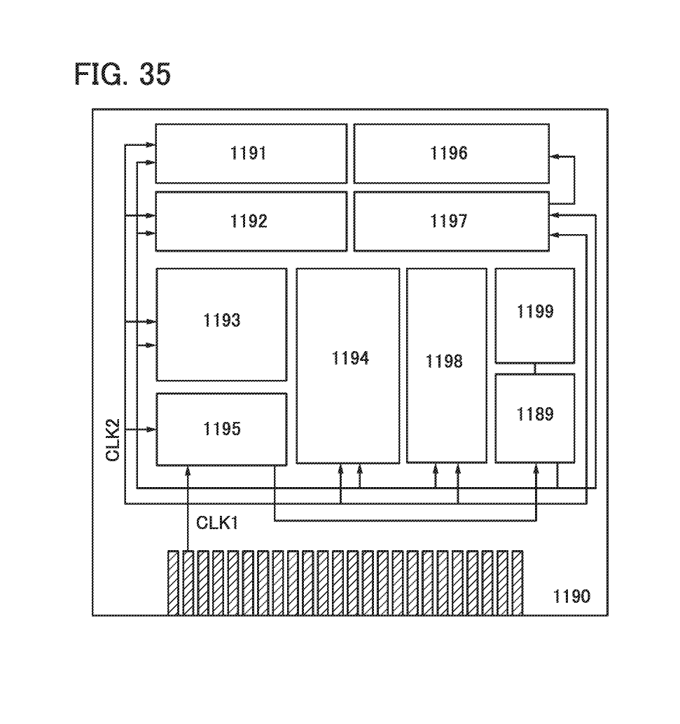

FIG. 35 is a block diagram illustrating a configuration example of a CPU at least partly including any of the transistors described in the above embodiments.

The CPU illustrated in FIG. 35 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198 (BUS I/F), a rewritable ROM 1199, and a ROM interface (ROM I/F) 1189. A semiconductor substrate, an SOI substrate, a glass substrate, or the like is used as the substrate 1190. The ROM 1199 and the ROM interface 1189 may be provided over a separate chip. Needless to say, the CPU in FIG. 35 is just an example with a simplified configuration, and an actual CPU may have a variety of configurations depending on the application. For example, the CPU may have the following configuration: a structure including the CPU illustrated in FIG. 35 or an arithmetic circuit is considered as one core; a plurality of the cores are included; and the cores operate in parallel to each other. The number of bits that the CPU can process in an internal arithmetic circuit or in a data bus can be, for example, 8, 16, 32, or 64.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 processes an interrupt request from an external input/output device or a peripheral circuit depending on its priority or a mask state. The register controller 1197 generates an address of the register 1196, and reads/writes data from/to the register 1196 depending on the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 on the basis of a reference clock signal CLK1, and supplies the internal clock signal CLK2 to the above circuits.

In the CPU illustrated in FIG. 35, a memory cell is provided in the register 1196. For the memory cell of the register 1196, any of the transistors described in the above embodiments can be used.

In the CPU illustrated in FIG. 35, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

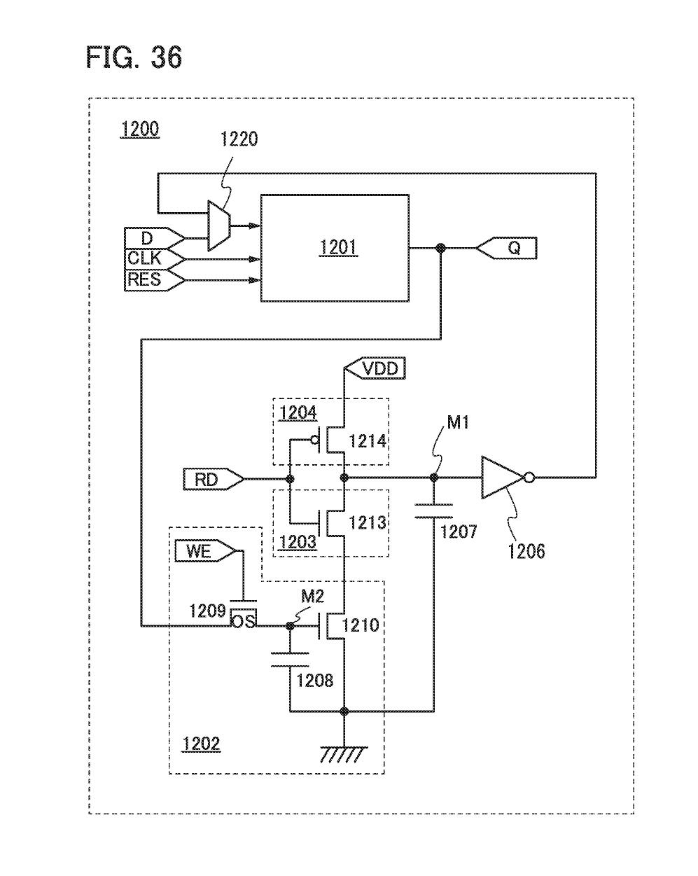

FIG. 36 is an example of a circuit diagram of a memory element that can be used for the register 1196. A memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the memory device described in the above embodiment can be used as the circuit 1202. When supply of a power supply voltage to the memory element 1200 is stopped, a ground potential (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a wiring that can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a wiring that can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the wiring that can supply a low power supply potential (e.g., a GND line). The other of the pair of electrodes of the capacitor 1208 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1208 is electrically connected to the wiring that can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the first gate (first gate electrode) of the transistor 1209. As for each of the switch 1203 and the switch 1204, a conduction state or a non-conduction state between the first terminal and the second terminal is selected by the control signal RD that is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 36 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 36, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 36, the transistors included in the memory element 1200 except for the transistor 1209 can each be a transistor in which a channel is formed in a layer formed using a semiconductor other than an oxide semiconductor or in the substrate 1190. For example, the transistor can be a transistor whose channel is formed in a silicon layer or a silicon substrate. Alternatively, a transistor in which a channel is formed in an oxide semiconductor film can be used for all the transistors in the memory element 1200. Further alternatively, in the memory element 1200, a transistor in which a channel is formed in an oxide semiconductor film can be included besides the transistor 1209, and a transistor in which a channel is formed in a layer formed using a semiconductor other than an oxide semiconductor or in the substrate 1190 can be used for the rest of the transistors.

As the circuit 1201 in FIG. 36, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 that is provided in the circuit 1202.

The off-state current of a transistor in which a channel is formed in an oxide semiconductor film is extremely small. For example, the off-state current of a transistor in which a channel is formed in an oxide semiconductor film is significantly smaller than that of a transistor in which a channel is formed in silicon having crystallinity. Thus, when the transistor is used as the transistor 1209, a signal retained in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Thus, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 changes to some degree.

By using the above-described memory element 1200 in a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Thus, the power supply can be stopped even for a short time in the processor or one or a plurality of logic circuits included in the processor, resulting in lower power consumption.

Although the memory element 1200 is used in a CPU in this embodiment, the memory element 1200 can also be used in an LSI, such as a digital signal processor (DSP), a custom LSI, or a programmable logic device (PLD), and a radio frequency identification (RF-ID) tag.

At least part of this embodiment can be implemented in combination with any of the embodiments described in this specification as appropriate.

### Embodiment 7

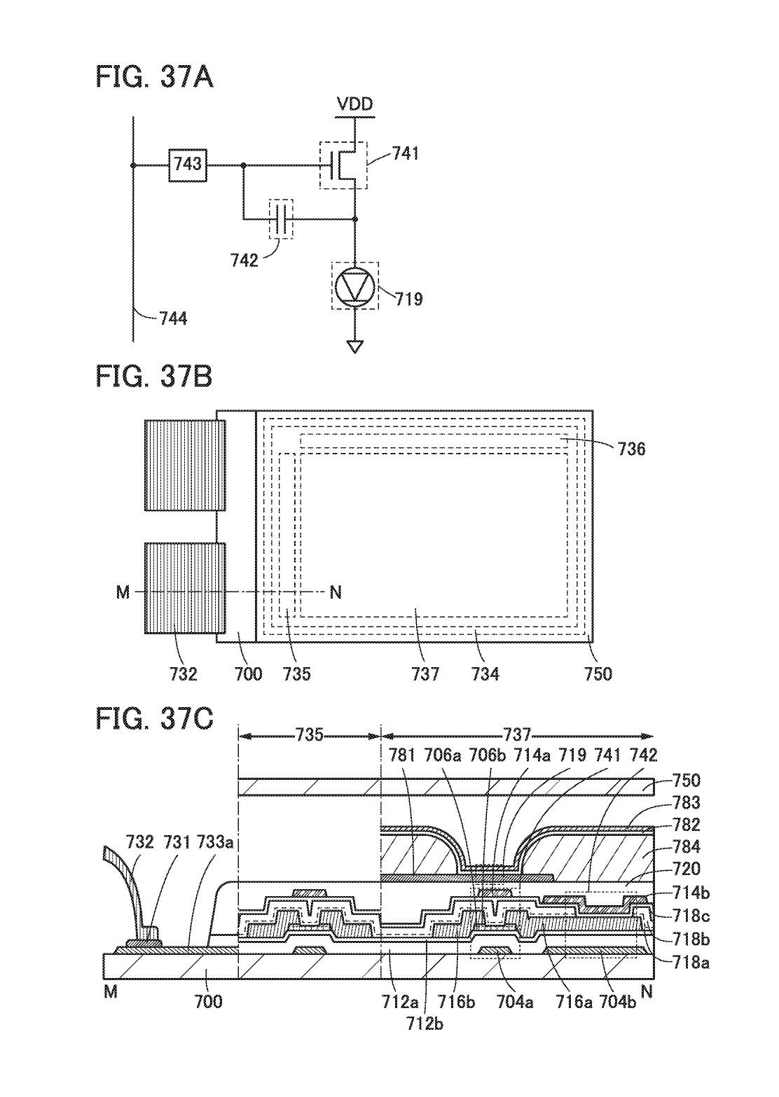

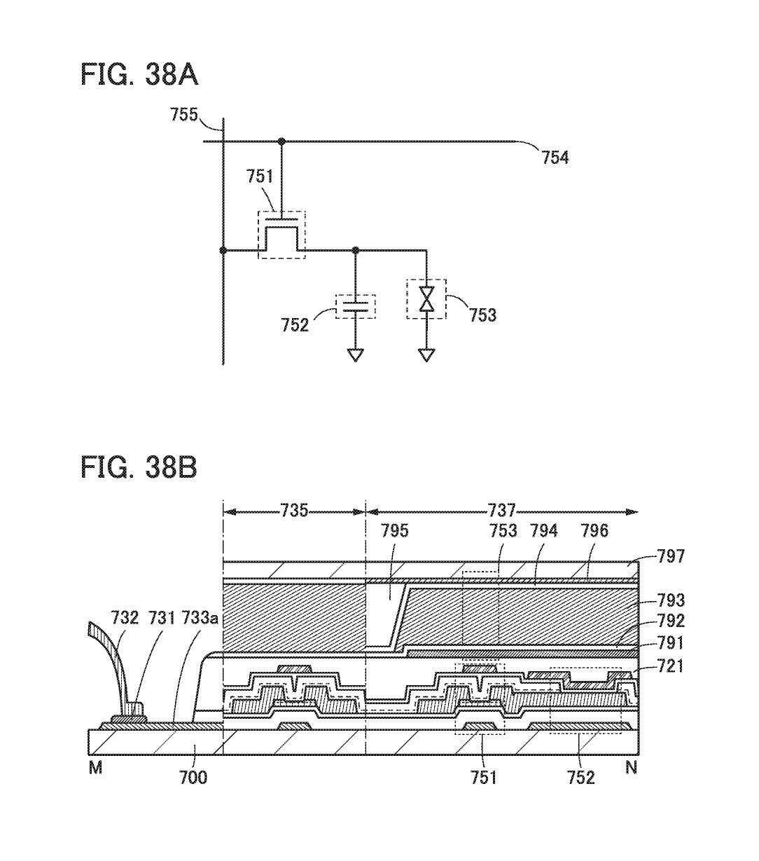

In this embodiment, a display device of one embodiment of the present invention will be described with reference to FIGS. 37A to 37C and FIGS. 38A and 38B.

Examples of a display element provided in the display device include a liquid crystal element (also referred to as a liquid crystal display element) and a light-emitting element (also referred to as a light-emitting display element). The light-emitting element includes, in its category, an element whose luminance is controlled by a current or voltage, and specifically includes, in its category, an inorganic electroluminescent (EL) element, an organic EL element, and the like. A display device including an EL element (EL display device) and a display device including a liquid crystal element (liquid crystal display device) are described below as examples of the display device.

Note that the display device described below includes in its category a panel in which a display element is sealed and a module in which an IC such as a controller is mounted on the panel.

The display device described below refers to an image display device or a light source (including a lighting device). The display device includes any of the following modules: a module provided with a connector such as an FPC or TCP; a module in which a printed wiring board is provided at the end of TCP; and a module in which an integrated circuit (IC) is mounted directly on a display element by a COG method.

FIGS. 37A to 37C show an example of an EL display device according to one embodiment of the present invention. FIG. 37A is a circuit diagram of a pixel in an EL display device. FIG. 37B is a top view showing the whole of the EL display device. FIG. 37C is a cross-sectional view taken along part of dashed-dotted line M-N in FIG. 37B.

FIG. 37A illustrates an example of a circuit diagram of a pixel used in an EL display device.

Note that in this specification and the like, it might be possible for those skilled in the art to constitute one embodiment of the invention even when portions to which all the terminals of an active element (e.g., a transistor or a diode), a passive element (e.g., a capacitor or a resistor), or the like are connected are not specified. In other words, one embodiment of the invention can be clear even when connection portions are not specified. Further, in the case where a connection portion is disclosed in this specification and the like, it can be determined that one embodiment of the invention in which a connection portion is not specified is disclosed in this specification and the like, in some cases. Particularly in the case where the number of portions to which a terminal is connected might be more than one, it is not necessary to specify the portions to which the terminal is connected. Therefore, it might be possible to constitute one embodiment of the invention by specifying only portions to which some of terminals of an active element (e.g., a transistor or a diode), a passive element (e.g., a capacitor or a resistor), or the like are connected.

Note that in this specification and the like, it might be possible for those skilled in the art to specify the invention when at least the connection portion of a circuit is specified. Alternatively, it might be possible for those skilled in the art to specify the invention when at least a function of a circuit is specified. In other words, when a function of a circuit is specified, one embodiment of the present invention can be clear. Further, it can be determined that one embodiment of the present invention whose function is specified is disclosed in this specification and the like. Therefore, when a connection portion of a circuit is specified, the circuit is disclosed as one embodiment of the invention even when a function is not specified, and one embodiment of the invention can be constituted. Alternatively, when a function of a circuit is specified, the circuit is disclosed as one embodiment of the invention even when a connection portion is not specified, and one embodiment of the invention can be constituted.

The EL display device illustrated in FIG. 37A includes a switching element 743, a transistor 741, a capacitor 742, and a light-emitting element 719.

Note that FIG. 37A and the like each illustrate an example of a circuit structure; therefore, a transistor can be provided additionally. In contrast, for each node in FIG. 37A and the like, it is possible not to provide an additional transistor, switch, passive element, or the like.

A gate of the transistor 741 is electrically connected to one terminal of the switching element 743 and one electrode of the capacitor 742. A source of the transistor 741 is electrically connected to the other electrode of the capacitor 742 and one electrode of the light-emitting element 719. A drain of the transistor 741 is supplied with a power supply potential VDD. The other terminal of the switching element 743 is electrically connected to a signal line 744. A constant potential is supplied to the other electrode of the light-emitting element 719. The constant potential is a ground potential GND or a potential lower than the ground potential GND.

It is preferable to use a transistor as the switching element 743. When the transistor is used as the switching element, the area of a pixel can be reduced, so that the EL display device can have high resolution. As the switching element 743, a transistor formed through the same step as the transistor 741 can be used, so that EL display devices can be manufactured with high productivity. Note that as the transistor 741 and/or the switching element 743, any of the above-described transistors can be used, for example.

FIG. 37B is a top view of the EL display device. The EL display device includes a substrate 700, a substrate 750, a sealant 734, a driver circuit 735, a driver circuit 736, a pixel 737, and an FPC 732. The sealant 734 is provided between the substrate 700 and the substrate 750 so as to surround the pixel 737, the driver circuit 735, and the driver circuit 736. Note that the driver circuit 735 and/or the driver circuit 736 may be provided outside the sealant 734.

FIG. 37C is a cross-sectional view of the EL display device taken along part of dashed-dotted line M-N in FIG. 37B.

FIG. 37C illustrates a structure of the transistor 741 including a conductor 704a over the substrate 700; an insulator 712a over the conductor 704a; an insulator 712b over the insulator 712a; a semiconductor 706a and a semiconductor 706b which are over the insulator 712b and overlaps the conductor 704a; a conductor 716a and a conductor 716b in contact with the semiconductor 706a and the semiconductor 706b; an insulator 718a over the semiconductor 706b, the conductor 716a, and the conductor 716b; an insulator 718b over the insulator 718a; an insulator 718c over the insulator 718b; and a conductor 714a that is over the insulator 718c and overlaps the semiconductor 706b. Note that the structure of the transistor 741 is just an example; the transistor 741 may have a structure different from that illustrated in FIG. 37C.

Thus, in the transistor 741 illustrated in FIG. 37C, the conductor 704a serves as a gate, the insulator 712a and the insulator 712b serve as a gate insulator, the conductor 716a serves as a source, the conductor 716b serves as a drain, the insulator 718a, the insulator 718b, and the insulator 718c serve as a gate insulator, and the conductor 714a serves as a gate. Note that in some cases, electrical characteristics of the semiconductors 706a and 706b change if light enters the semiconductor. To prevent this, it is preferable that one or more of the conductor 704a, the conductor 716a, the conductor 716b, and the conductor 714a have a light-blocking property.

Note that the interface between the insulator 718a and the insulator 718b is indicated by a broken line. This means that the boundary between them is not clear in some cases. For example, in the case where the insulator 718a and the insulator 718b are formed using insulators of the same kind, the insulator 718a and the insulator 718b are not distinguished from each other in some cases depending on an observation method.

FIG. 37C illustrates a structure of the capacitor 742 including a conductor 704b over the substrate; the insulator 712a over the conductor 704b; the insulator 712b over the insulator 712a; the conductor 716a that is over the insulator 712b and overlaps the conductor 704b; the insulator 718a over the conductor 716a; the insulator 718b over the insulator 718a; the insulator 718c over the insulator 718b; and a conductor 714b that is over the insulator 718c and overlaps the conductor 716a. In this structure, part of the insulator 718a and part of the insulator 718b are removed in a region where the conductor 716a and the conductor 714b overlap each other.

In the capacitor 742, each of the conductor 704b and the conductor 714b serves as one electrode, and the conductor 716a serves as the other electrode.

Thus, the capacitor 742 can be formed using a film of the transistor 741. The conductor 704a and the conductor 704b are preferably conductors of the same kind, in which case the conductor 704a and the conductor 704b can be formed through the same step. Furthermore, the conductor 714a and the conductor 714b are preferably conductors of the same kind, in which case the conductor 714a and the conductor 714b can be formed through the same step.

The capacitor 742 illustrated in FIG. 37C has a large capacitance per area occupied by the capacitor. Therefore, the EL display device illustrated in FIG. 37C has high display quality. Note that although the capacitor 742 illustrated in FIG. 37C has the structure in which the part of the insulator 718a and the part of the insulator 718b are removed to reduce the thickness of the region where the conductor 716a and the conductor 714b overlap with each other, the structure of the capacitor according to one embodiment of the present invention is not limited to the structure. For example, a structure in which a part of the insulator 718c is removed to reduce the thickness of the region where the conductor 716a and the conductor 714b overlap with each other may be used.

An insulator 720 is provided over the transistor 741 and the capacitor 742. Here, the insulator 720 may have an opening portion reaching the conductor 716a that serves as the source of the transistor 741. A conductor 781 is provided over the insulator 720. The conductor 781 may be electrically connected to the transistor 741 through the opening portion in the insulator 720.

A partition wall 784 having an opening portion reaching the conductor 781 is provided over the conductor 781. A light-emitting layer 782 in contact with the conductor 781 through the opening portion provided in the partition wall 784 is provided over the partition wall 784. A conductor 783 is provided over the light-emitting layer 782. A region where the conductor 781, the light-emitting layer 782, and the conductor 783 overlap with one another serves as the light-emitting element 719.

So far, examples of the EL display device are described. Next, an example of a liquid crystal display device is described.

FIG. 38A is a circuit diagram illustrating a configuration example of a pixel of a liquid crystal display device. A pixel shown in FIGS. 38A and 38B includes a transistor 751, a capacitor 752, and an element (liquid crystal element) 753 in which a space between a pair of electrodes is filled with a liquid crystal.

One of a source and a drain of the transistor 751 is electrically connected to a signal line 755, and a gate of the transistor 751 is electrically connected to a scan line 754.

One electrode of the capacitor 752 is electrically connected to the other of the source and the drain of the transistor 751, and the other electrode of the capacitor 752 is electrically connected to a wiring for supplying a common potential.

One electrode of the liquid crystal element 753 is electrically connected to the other of the source and the drain of the transistor 751, and the other electrode of the liquid crystal element 753 is electrically connected to a wiring to which a common potential is supplied. The common potential supplied to the wiring electrically connected to the other electrode of the capacitor 752 may be different from that supplied to the other electrode of the liquid crystal element 753.

Note that the description of the liquid crystal display device is made on the assumption that the top view of the liquid crystal display device is similar to that of the EL display device. FIG. 38B is a cross-sectional view of the liquid crystal display device taken along dashed-dotted line M-N in FIG. 37B. In FIG. 38B, the FPC 732 is connected to the wiring 733a via the terminal 731. Note that the wiring 733a may be formed using the same kind of conductor as the conductor of the transistor 751 or using the same kind of semiconductor as the semiconductor of the transistor 751.

For the transistor 751, the description of the transistor 741 is referred to. For the capacitor 752, the description of the capacitor 742 is referred to. Note that the structure of the capacitor 752 in FIG. 38B corresponds to, but is not limited to, the structure of the capacitor 742 in FIG. 37C.

Note that in the case where an oxide semiconductor is used as the semiconductor of the transistor 751, the off-state current of the transistor 751 can be extremely small. Therefore, an electric charge held in the capacitor 752 is unlikely to leak, so that the voltage applied to the liquid crystal element 753 can be maintained for a long time. Accordingly, the transistor 751 can be kept off during a period in which moving images with few motions or a still image are/is displayed, whereby power for the operation of the transistor 751 can be saved in that period; accordingly a liquid crystal display device with low power consumption can be provided. Furthermore, the area occupied by the capacitor 752 can be reduced; thus, a liquid crystal display device with a high aperture ratio or a high-resolution liquid crystal display device can be provided.

An insulator 721 is provided over the transistor 751 and the capacitor 752. The insulator 721 has an opening portion reaching the transistor 751. A conductor 791 is provided over the insulator 721. The conductor 791 is electrically connected to the transistor 751 through the opening portion in the insulator 721.

An insulator 792 serving as an alignment film is provided over the conductor 791. A liquid crystal layer 793 is provided over the insulator 792. An insulator 794 serving as an alignment film is provided over the liquid crystal layer 793. A spacer 795 is provided over the insulator 794. A conductor 796 is provided over the spacer 795 and the insulator 794. A substrate 797 is provided over the conductor 796.

Owing to the above-described structure, a display device including a capacitor occupying a small area, a display device with high display quality, or a high-resolution display device can be provided.

For example, in this specification and the like, a display element, a display device which is a device including a display element, a light-emitting element, and a light-emitting device which is a device including a light-emitting element can employ various modes or can include various elements. The display element, the display device, the light-emitting element, or the light-emitting device includes at least one of an electroluminescence (EL) element (e.g., an EL element including organic and inorganic materials, an organic EL element, or an inorganic EL element), an LED (e.g., a white LED, a red LED, a green LED, or a blue LED), a transistor (a transistor that emits light depending on current), an electron emitter, a liquid crystal element, electronic ink, an electrophoretic element, a grating light valve (GLV), a plasma display panel (PDP), a display element using micro electro mechanical system (MEMS), a digital micromirror device (DMD), a digital micro shutter (DMS), an interferometric modulator display (IMOD) element, a MEMS shutter display element, an optical-interference-type MEMS display element, an electrowetting element, a piezoelectric ceramic display, a display element including a carbon nanotube, and the like. In addition, display media whose contrast, luminance, reflectivity, transmittance, or the like is changed by electrical or magnetic effect may be included.

Note that examples of display devices having EL elements include an EL display. Examples of a display device including an electron emitter include a field emission display (FED), an SED-type flat panel display (SED: surface-conduction electron-emitter display), and the like. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Examples of a display device including electronic ink, Electronic Liquid Powder (registered trademark), or an electrophoretic element include electronic paper. In the case of a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes. Thus, power consumption can be further reduced.

Note that in the case of using an LED, graphene or graphite may be provided under an electrode or a nitride semiconductor of the LED. Graphene or graphite may be a multilayer film in which a plurality of layers are stacked. As described above, provision of graphene or graphite enables easy formation of a nitride semiconductor thereover, such as an n-type GaN semiconductor including crystals. Furthermore, a p-type GaN semiconductor including crystals or the like can be provided thereover, and thus the LED can be formed. Note that an AlN layer may be provided between the n-type GaN semiconductor including crystals and graphene or graphite. The GaN semiconductors included in the LED may be formed by MOCVD. Note that when the graphene is provided, the GaN semiconductors included in the LED can also be formed by a sputtering method.

### Embodiment 8

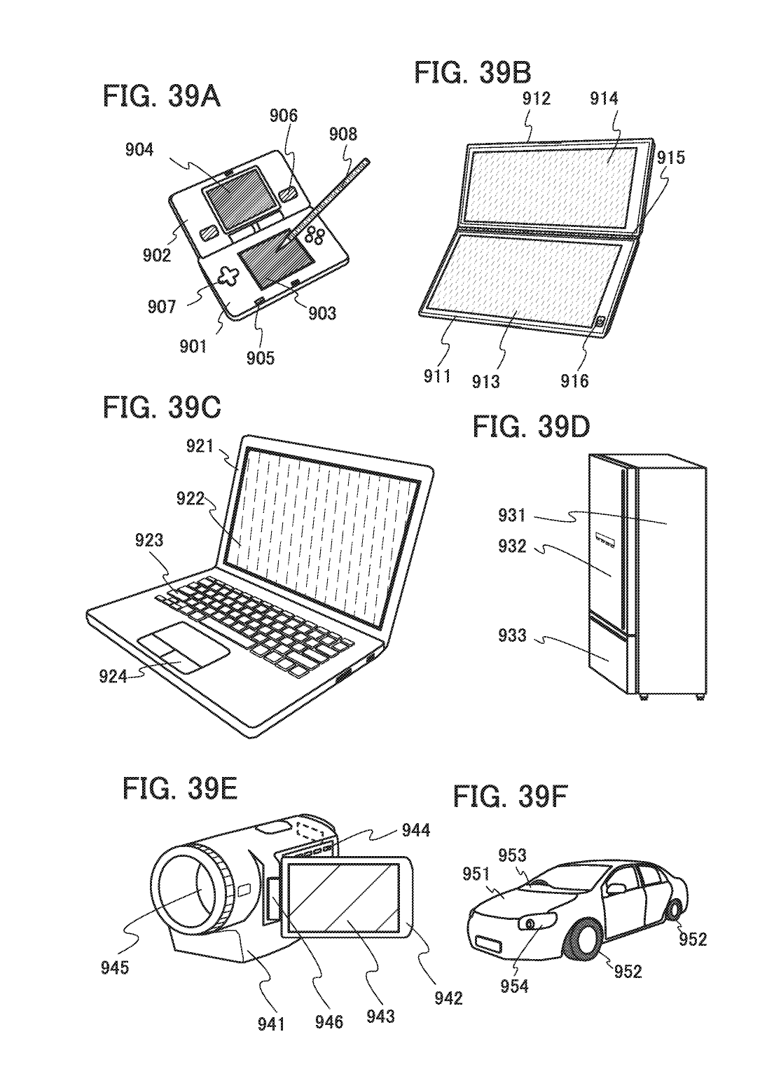

The semiconductor device of one embodiment of the present invention can be used for display devices, personal computers, or image reproducing devices provided with recording media (typically, devices that reproduce the content of recording media such as digital versatile discs (DVDs) and have displays for displaying the reproduced images. Other examples of electronic devices that can be equipped with the semiconductor device of one embodiment of the present invention are cellular phones, game machines including portable game machines, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 39A to 39F illustrate specific examples of these electronic devices.

FIG. 39A illustrates a portable game machine, which includes a housing 901, a housing 902, a display portion 903, a display portion 904, a microphone 905, a speaker 906, an operation key 907, a stylus 908, and the like. Although the portable game machine in FIG. 39A has the two display portions 903 and 904, the number of display portions included in a portable game machine is not limited to this.

FIG. 39B illustrates a portable data terminal, which includes a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. Images displayed on the first display portion 913 may be switched in accordance with the angle at the joint 915 between the first housing 911 and the second housing 912. A display device with a position input function may be used as at least one of the first display portion 913 and the second display portion 914. Note that the position input function can be added by providing a touch panel in a display device. Alternatively, the position input function can be added by provision of a photoelectric conversion element called a photosensor in a pixel portion of a display device.

FIG. 39C illustrates a laptop personal computer, which includes a housing 921, a display portion 922, a keyboard 923, a pointing device 924, and so on.

FIG. 39D illustrates an electric refrigerator-freezer, which includes a housing 931, a refrigerator door 932, a freezer door 933, and others.

FIG. 39E illustrates a video camera, which includes a first housing 941, a second housing 942, a display portion 943, operation keys 944, a lens 945, a joint 946, and the like. The operation keys 944 and the lens 945 are provided in the first housing 941, and the display portion 943 is provided in the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 39F illustrates a car including a car body 951, wheels 952, a dashboard 953, lights 954, and the like.

At least part of this embodiment can be implemented in combination with any of the other embodiments described in this specification as appropriate.

### Embodiment 9

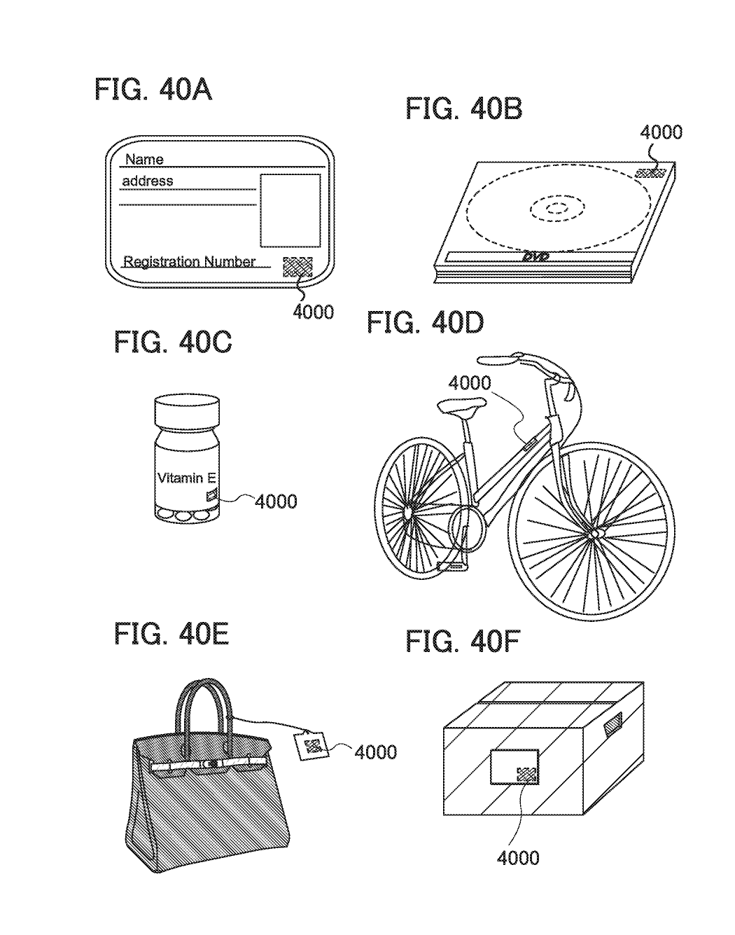

In this embodiment, application examples of an RF device of one embodiment of the present invention will be described with reference to FIGS. 40A to 40F. The RF device is widely used and can be provided for, for example, products such as bills, coins, securities, bearer bonds, documents (e.g., driver's licenses or residence cards, see FIG. 40A), recording media (e.g., DVD software or video tapes, see FIG. 40B), packaging containers (e.g., wrapping paper or bottles, see FIG. 40C), vehicles (e.g., bicycles, see FIG. 40D), personal belongings (e.g., bags or glasses), foods, plants, animals, human bodies, clothing, household goods, medical supplies such as medicine and chemicals, and electronic devices (e.g., liquid crystal display devices, EL display devices, television sets, or cellular phones), or tags on products (see FIGS. 40E and 40F).

An RF device 4000 of one embodiment of the present invention is fixed to a product by being attached to a surface thereof or embedded therein. For example, the RF device 4000 is fixed to each product by being embedded in paper of a book, or embedded in an organic resin of a package. Since the RF device 4000 of one embodiment of the present invention can be reduced in size, thickness, and weight, it can be fixed to a product without spoiling the design of the product. Furthermore, bills, coins, securities, bearer bonds, documents, or the like can have an identification function by being provided with the RF device 4000 of one embodiment of the present invention, and the identification function can be utilized to prevent counterfeiting. Moreover, the efficiency of a system such as an inspection system can be improved by providing the RF device of one embodiment of the present invention for packaging containers, recording media, personal belongings, foods, clothing, household goods, electronic appliances, or the like. Vehicles can also have higher security against theft or the like by being provided with the RF device of one embodiment of the present invention.

As described above, by using the RF device of one embodiment of the present invention for each application described in this embodiment, power for operation such as writing or reading of data can be reduced, which results in an increase in the maximum communication distance. Moreover, data can be retained for an extremely long period even in the state where power is not supplied; thus, the RF device can be preferably used for application in which data is not frequently written or read.

At least part of this embodiment can be implemented in combination with any of the other embodiments described in this specification as appropriate.

This application is based on Japanese Patent Application serial no. 2014-247831 filed with Japan Patent Office on Dec. 8, 2014, the entire contents of which are hereby incorporated by reference.

What is claimed is:

1. A transistor comprising:
a gate electrode;
a gate insulator; and
a crystalline oxide semiconductor,
wherein a released gas of the crystalline oxide semiconductor observed as a water molecule with a thermal desorption spectrometer is 1.0/nm³ or less.

2. The transistor according to claim 1,
wherein a water molecule does not exist in the crystalline oxide semiconductor.

3. The transistor according to claim 1,
wherein the crystalline oxide semiconductor is a CAAC-OS.

4. The transistor according to claim 1,
wherein the crystalline oxide semiconductor is a single crystal.

5. The transistor according to claim 1,
wherein the released gas is 0.1/nm³ or less.

6. The transistor according to claim 1,
wherein the crystalline oxide semiconductor includes an oxide containing at least one of elements selected from indium, zinc and an element M, and
wherein the element M is aluminum, gallium, yttrium or tin.

7. A transistor comprising:
a gate electrode;
a gate insulator; and
a crystalline oxide semiconductor,
wherein the crystalline oxide semiconductor includes H or OH,
wherein the H or the OH reacts with O in the crystalline oxide semiconductor to generate a water molecule when the H or the OH is released to the outside from the crystalline oxide semiconductor, and
wherein a released gas observed as a water molecule with a thermal desorption spectrometer is 1.0/nm³ or less.

8. The transistor according to claim 7,
wherein a water molecule does not exist in the crystalline oxide semiconductor.

9. The transistor according to claim 7,
wherein the crystalline oxide semiconductor is a CAAC-OS.

10. The transistor according to claim 7,
wherein the crystalline oxide semiconductor is a single crystal.

11. The transistor according to claim 7,
wherein the released gas observed is 0.1/nm³ or less.

12. The transistor according to claim 7,
wherein the crystalline oxide semiconductor includes an oxide containing at least one of elements selected from indium, zinc and an element M, and
wherein the element M is aluminum, gallium, yttrium or tin.

13. A transistor comprising
a gate electrode;
a gate insulator; and
a crystalline oxide semiconductor,
wherein the crystalline oxide semiconductor includes H or OH
wherein the H or the OH reacts with O in the crystalline oxide semiconductor to generate a water molecule when the H or the OH is released to the outside from the crystalline oxide semiconductor through a side surface of the crystalline oxide semiconductor, and
wherein a released gas observed as a water molecule with a thermal desorption spectrometer is 1.0/nm³ or less.

14. The transistor according to claim 13,
wherein a water molecule does not exist in the crystalline oxide semiconductor.

15. The transistor according to claim 13,
wherein the crystalline oxide semiconductor is a CAAC-OS.

16. The transistor according to claim 13,
wherein the crystalline oxide semiconductor is a single crystal.

17. The transistor according to claim 13,
wherein the released gas observed is 0.1/nm³ or less.

18. The transistor according to claim 13,
wherein the crystalline oxide semiconductor includes an oxide containing at least one of elements selected from indium, zinc and an element M, and
wherein the element M is aluminum, gallium, yttrium or tin.

19. A transistor comprising:
a gate electrode;
a gate insulator; and
a crystalline oxide semiconductor,
wherein a water molecule does not exist in the crystalline oxide semiconductor.
